(19) United States
(12) Patent Application Publication
(10) Pub. No.: US 2024/0327701 A1
(43) Pub. Date: Oct. 3, 2024

(54) HIGH MOLECULAR WEIGHT COMPOUNDS HAVING INDENO-DIBENZOHETEROLE STRUCTURE AS PARTIAL STRUCTURE, AND ORGANIC ELECTROLUMINESCENT ELEMENTS COMPRISING SAID HIGH MOLECULAR WEIGHT COMPOUNDS

(71) Applicant: HODOGAYA CHEMICAL CO., LTD., Tokyo (JP)

(72) Inventors: Hiroki HIRAI, Tokyo (JP); Kazunori TOGASHI, Tokyo (JP); Yuta SAEGUSA, Tokyo (JP); Mika SHINODA, Tokyo (JP); Hideyoshi KITAHARA, Tokyo (JP)

(73) Assignee: HODOGAYA CHEMICAL CO., LTD., Tokyo (JP)

(21) Appl. No.: 18/279,697

(22) PCT Filed: Mar. 7, 2022
(86) PCT No.: PCT/JP2022/009777

§ 371 Date: Aug. 31, 2023

(30) Foreign Application Priority Data
Mar. 12, 2021 (JP) 2021-039855

(51) Int. Cl. C09K 11/06; H10K 50/11; H10K 50/15; H10K 85/10

(52) U.S. Cl. CPC C09K 11/06; H10K 50/11; H10K 50/15; H10K 85/111; C09K 2211/145

(57) ABSTRACT

An objective of the invention is to provide a high molecular weight material having excellent hole injectability and transportability, electron blockability, and high stability in a thin-film state. An objective of the invention is to provide an organic EL device including an organic layer (thin film) formed by the high molecular weight material and having high luminous efficiency and long lifetime. The invention relates to a high molecular weight compound including, as a repeating unit, a triarylamine structure represented by general formula (1) below. (In the formula, R₁ and R₂ each independently represent a substituted or unsubstituted alkyl group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, or a substituted or unsubstituted polyether group having 1 to 40 carbon atoms.)

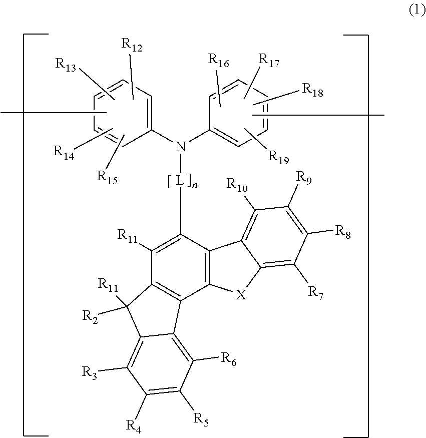

### TECHNICAL FIELD

The present invention relates to high molecular weight compounds suitable for organic electroluminescent devices (organic EL devices) which are self-emissive devices suitably used in various types of display apparatuses, and organic EL devices including the same.

### BACKGROUND ART

Organic EL devices are self-emissive devices, and are therefore brighter, have better visibility, and are capable of clearer display compared to liquid crystal devices. Hence, active studies have been carried out on organic EL devices.

An organic EL device is constituted by interposing a thin film (organic layer) made of an organic compound between an anode and a cathode. Thin film formation methods are broadly categorized into the vacuum deposition method and the coating method. The vacuum deposition method is a technique in which a thin film is formed on a substrate in vacuum mainly using a low molecular weight compound, and this technique is already in practical use. The coating method, on the other hand, is a technique in which a thin film is formed on a substrate through ink-jetting, printing, etc., using a solution composed mainly of a high molecular weight compound. The coating method has high material usage efficiency and is suitable for area enlargement and resolution enhancement, and is therefore an essential technique for future large-area organic EL displays.

The vacuum deposition method employing low molecular weight materials suffers from extremely low material usage efficiency. Also, enlarging the substrate may increase shadow mask warpage, thus posing difficulty in uniform deposition onto large substrates.

This technique also suffers from high manufacturing costs.

In contrast, with high molecular weight materials, a uniform film can be formed even on a large substrate by applying a solution prepared by dissolving the material in an organic solvent. Thus, high molecular weight materials can be used for coating methods, typified by ink-jetting and printing. In this way, material usage efficiency can be improved, and device manufacturing cost can therefore be significantly reduced.

Various studies have been conducted heretofore regarding organic EL devices employing high molecular weight materials, but device properties, such as luminous efficiency and longevity, are not necessarily sufficient (for example, see Patent Literatures 1 to 5).

Meanwhile, a fluorene polymer called “TFB” has been known as a hole-transporting material typically used heretofore in high molecular weight organic EL devices (see Patent Literatures 6 and 7). Unfortunately, TFB has insufficient hole transportability as well as insufficient electron blockability, which causes portions of electrons to pass through the light-emitting layer, therefore making it impossible to expect improvements in luminous efficiency. Also, film adhesiveness with adjacent layers is poor, therefore making it impossible to expect long device life.

### CITATION LIST

### Patent Literature

Patent Literature 1: US Patent Application Publication No. 2008/0274303
Patent Literature 2: Japanese Unexamined Patent Publication No. 2007-119763
Patent Literature 3: US Patent Application Publication No. 2010/0176377
Patent Literature 4: Japanese Unexamined Patent Publication No. 2007-177225
Patent Literature 5: U.S. Pat. No. 7,651,746
Patent Literature 6: International Publication No. 1999/054385
Patent Literature 7: International Publication No. 2005/059951

### SUMMARY OF INVENTION

An objective of the invention is to provide a high molecular weight material having excellent hole injectability and transportability, electron blockability, and high stability in a thin-film state.

An objective of the invention is to provide an organic EL device including an organic layer (thin film) formed by the high molecular weight material and having high luminous efficiency and long lifetime.

Inventors focused on the fact that triarylamines including an indeno-dibenzoheterole structure have high hole injectability and transportability and can be expected to achieve a wide bandgap, and, as a result of synthesizing and studying various triarylamine high molecular weight compounds including an indeno-dibenzoheterole structure, found a novel-structure high molecular weight compound that not only has hole injectability and transportability but also has a wide bandgap, excellent heat resistance and thin-film stability, to thus accomplish the present invention.

The present invention provides a high molecular weight compound including, as a repeating unit, a triarylamine structure represented by general formula (1) below.

The present invention provides an organic electroluminescent device including a pair of electrodes, and at least one organic layer interposed therebetween, wherein the organic layer contains the aforementioned high molecular weight compound as a constituent material.

In the organic EL device of the present invention, it is preferable that the organic layer is a hole transport layer, an electron blocking layer, a hole injection layer, or a light-emitting layer.

More specifically, the present invention is as described below.

{1}

A high molecular weight compound including, as a repeating unit, a triarylamine structural unit having an indeno-dibenzoheterole structure represented by general formula (1) below as a partial structure.

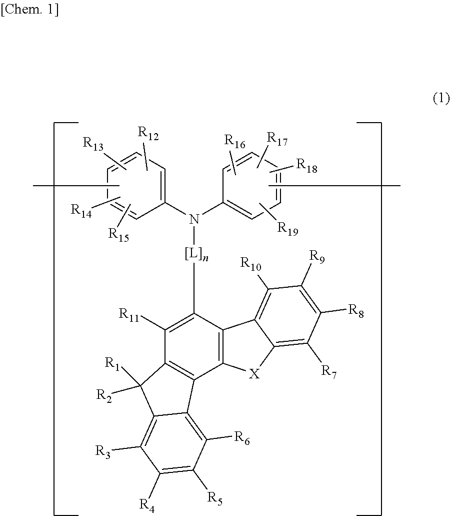

(wherein:
R₁ and R₂ each independently represent a substituted or unsubstituted alkyl group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, or a substituted or unsubstituted polyether group having 1 to 40 carbon atoms,
X represents an oxygen atom or a sulfur atom;
R₃ to R₁₁ each independently represent a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, a substituted or unsubstituted aryloxy group, a substituted or unsubstituted aryl group, or a substituted or unsubstituted heteroaryl group;
R₁₂ and R₁₆ each independently represent a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, or a substituted or unsubstituted aryloxy group, wherein R₁₂ and R₁₆ may be bonded to each other via a single bond, a methylene group optionally having a substituent, an oxygen atom, or a sulfur atom;
R₁₃ to R₁₅ and R₁₇ to R₁₉ each independently represent a hydrogen atom or a deuterium atom;
L represents a substituted or unsubstituted arylene group having 5 to 40 carbon atoms; and
n represents an integer from 0 to 3.)
   {2}

The high molecular weight compound as set forth in clause (I), including a repeating unit represented by general formula (2) below.

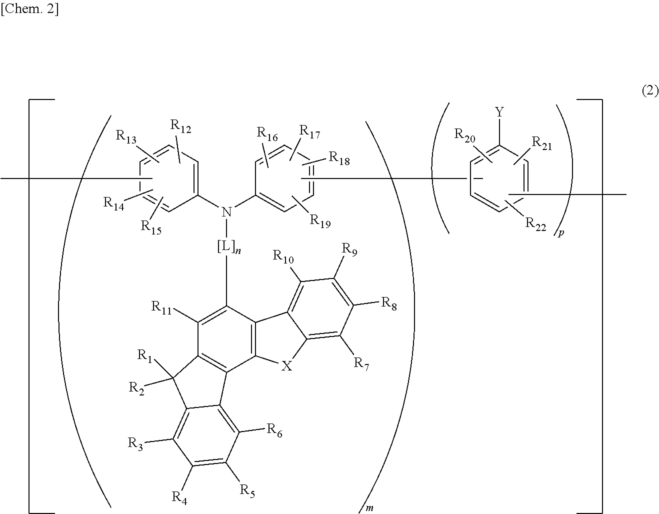

(wherein:
R₁ to R₁₉, X, L, and n are the same as in formula (1);
R₂₀ to R₂₂ each independently represent a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, or a substituted or unsubstituted aryloxy group;
Y represents a hydrogen atom, a deuterium atom, a substituted or unsubstituted amino group, a substituted or unsubstituted aryl group, or a substituted or unsubstituted heteroaryl group;
m and p are expressed in mole fraction;
m represents from 0.1 to 0.9; and
p represents from 0.1 to 0.9.)
   {3}

The high molecular weight compound as set forth in clause {1} or {2}, wherein X is an oxygen atom.

{4}

The high molecular weight compound as set forth in any one of clauses {1} to {3}, wherein R₁₂ to R₁₉ are each a hydrogen atom.

{5}

The high molecular weight compound as set forth in any one of clauses {1} to {4}, wherein R₃ to R₁₁ are each a hydrogen atom.

{6}

The high molecular weight compound as set forth in any one of clauses {2} to {5}, wherein R₃ to R₂₂ are each a hydrogen atom.

{7}

The high molecular weight compound as set forth in any one of clauses {2} to {6}, wherein Y is a hydrogen atom, a diphenylamino group, a phenyl group, a naphthyl group, a dibenzofuranyl group, a dibenzothienyl group, a phenanthrenyl group, a fluorenyl group, a carbazolyl group, an indenocarbazolyl group, or an acridinyl group.

{8}

The high molecular weight compound as set forth in any one of clauses {1} to {7}, wherein R₁ and R₂ each independently represent an alkyl group, an alkyloxy group, or a polyether group.

{9}

The high molecular weight compound as set forth in any one of clauses {1} to {8}, including a thermally cross-linkable structural unit as a repeating unit.

{10}

The high molecular weight compound as set forth in clause {9}, wherein the thermally cross-linkable structural unit is at least one type of thermally cross-linkable structural unit selected from the group consisting of general formulas (3aa) to (3bd) below.

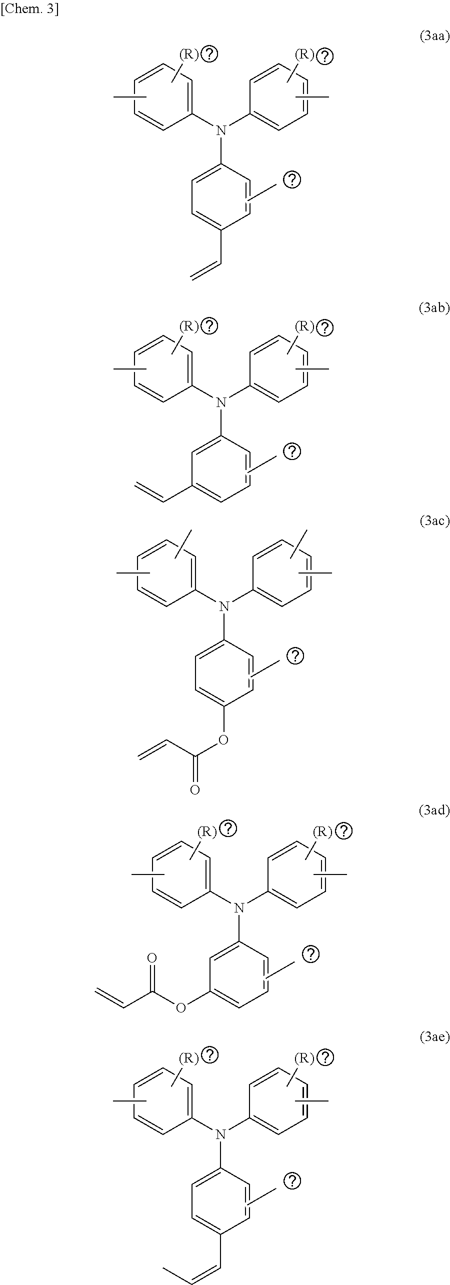

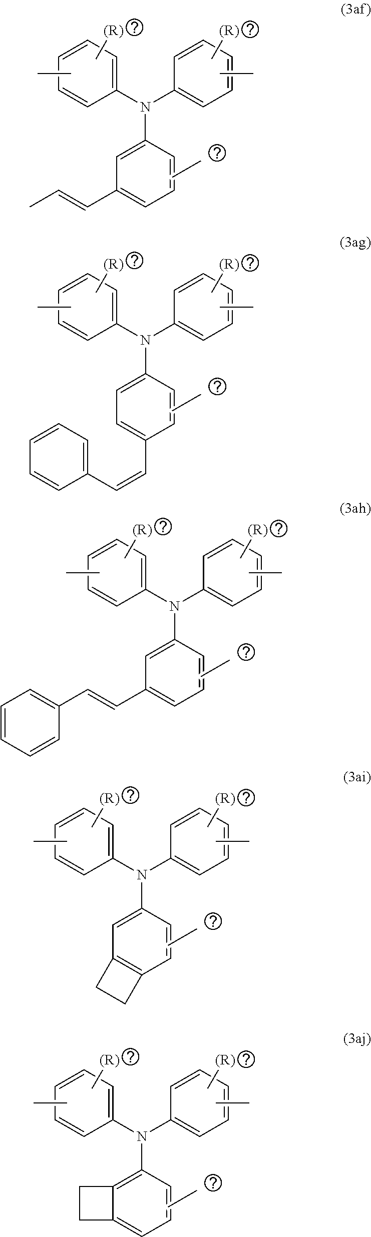

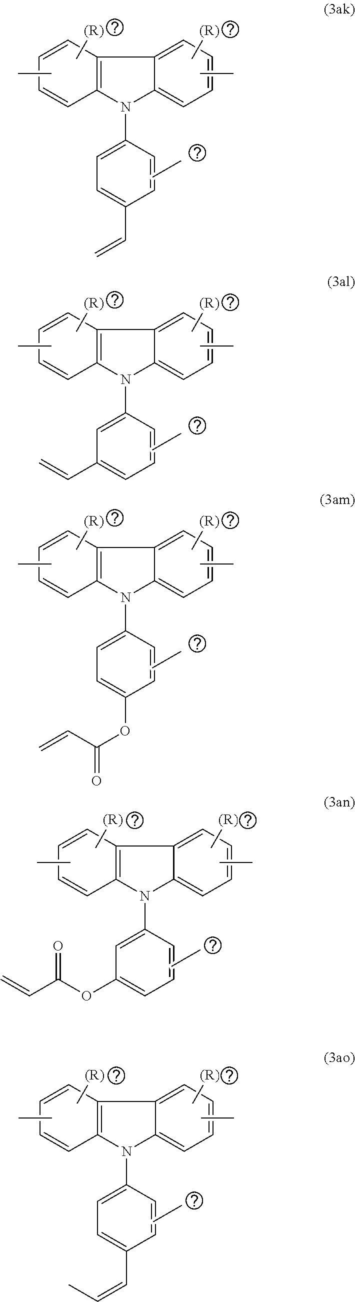

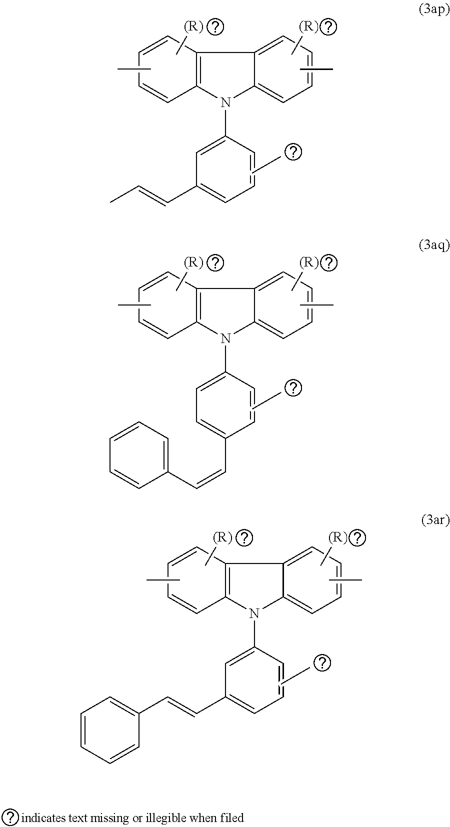

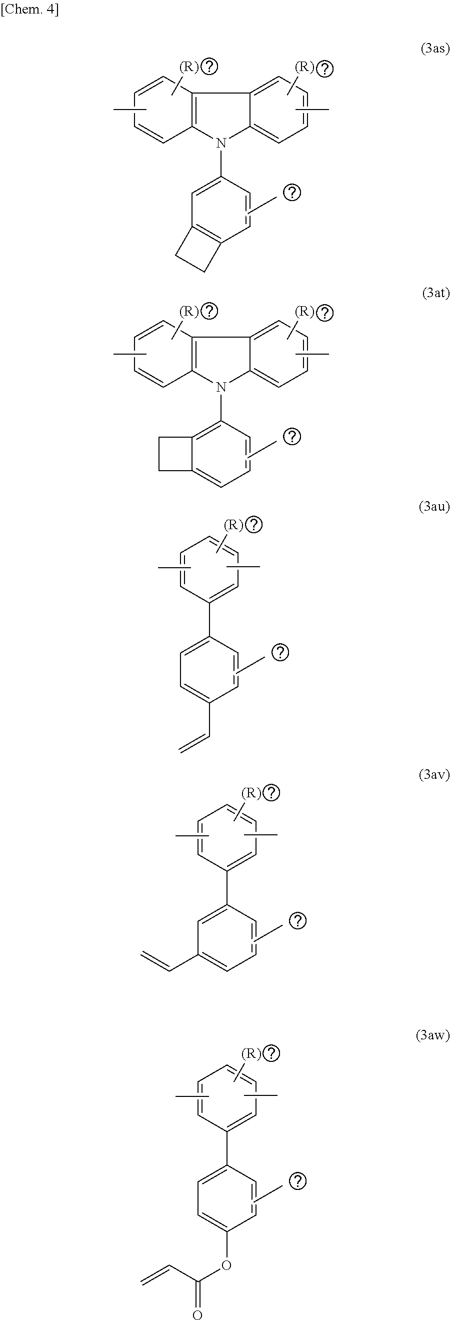

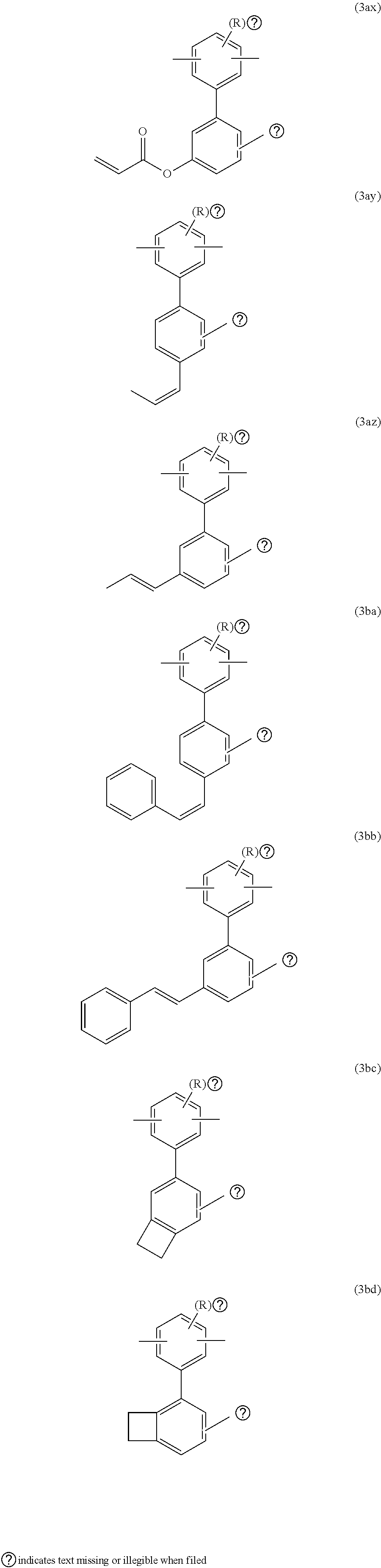

(wherein:
R independently represents a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, a substituted or unsubstituted aryloxy group, a substituted or unsubstituted aryl group, or a substituted or unsubstituted heteroaryl group;
a wavy line represents cis or trans;
a dotted line represents a bond to a main chain;
a represents an integer from 0 to 4; and
b represents an integer from 0 to 3.)
   {11}

An organic electroluminescent device including a pair of electrodes, and at least one layer of an organic layer interposed therebetween, wherein the organic layer contains the high molecular weight compound as set forth in any one of clauses {1} to {10}.

{12}

The organic electroluminescent device as set forth in clause {11}, wherein the organic layer is a hole transport layer.

{13}

The organic electroluminescent device as set forth in clause {11}, wherein the organic layer is an electron blocking layer.

{14}

The organic electroluminescent device as set forth in clause {11}, wherein the organic layer is a hole injection layer.

{15}

The organic electroluminescent device as set forth in clause {11}, wherein the organic layer is a light-emitting layer.

A high molecular weight compound including, as a repeating unit, a triarylamine structural unit having an indeno-dibenzoheterole structure represented by general formula (1) as a partial structure has such characteristics as:
(1) excellent hole injection properties;
(2) high hole mobility;
(3) wide bandgap and excellent electron blockability;
(4) stable thin-film state; and
(5) excellent heat resistance.

An organic EL device having an organic layer, such as a hole transport layer, an electron blocking layer, a hole injection layer, or a light-emitting layer, formed by the aforementioned high molecular weight compound between a pair of electrodes has such advantages as:
(1) high luminous efficiency and power efficiency;
(2) low practical driving voltage; and
(3) long lifetime.

### BRIEF DESCRIPTION OF DRAWINGS

FIG. 1 illustrates an example of a layer configuration of an organic EL device of the present invention.

FIG. 2 illustrates an example of a layer configuration of an organic EL device of the present invention.

FIG. 3 is a ¹H-NMR chart of High molecular weight compound A of the present invention synthesized in Example 1.

FIG. 4 is a ¹H-NMR chart of High molecular weight compound B of the present invention synthesized in Example 2.

FIG. 5 is a ¹H-NMR chart of High molecular weight compound C of the present invention synthesized in Example 3.

### DESCRIPTION OF EMBODIMENTS

### <High Molecular Weight Compound>

The high molecular weight compound of the present invention is a high molecular weight compound including, as a repeating unit, a triarylamine structural unit having an indeno-dibenzoheterole structural unit as a partial structure.

### <<Triarylamine Structural Unit>>

The triarylamine structural unit of the high molecular weight compound has an indeno-dibenzoheterole structure as a partial structure, and is represented by general formula (1) below.

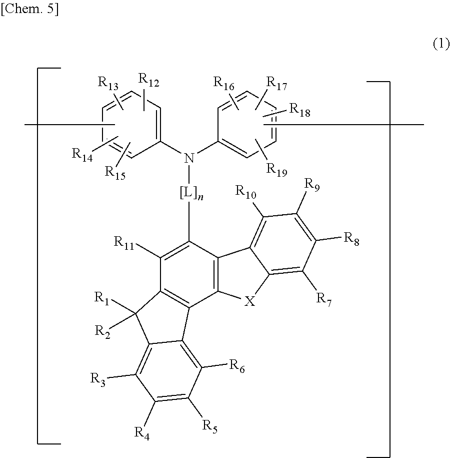

(In the formula:
R₁ and R₂ each independently represent a substituted or unsubstituted alkyl group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, or a substituted or unsubstituted polyether group having 1 to 40 carbon atoms;
X represents an oxygen atom or a sulfur atom; and
R₃ to R₁₁ each independently represent a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, a substituted or unsubstituted aryloxy group, a substituted or unsubstituted aryl group, or a substituted or unsubstituted heteroaryl group.
R₁₂ and R₁₆ each independently represent a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, or a substituted or unsubstituted aryloxy group, wherein R₁₂ and R₁₆ may be bonded to each other via a single bond, a methylene group optionally having a substituent, an oxygen atom, or a sulfur atom;
R₃ to R₁₅ and R₁₇ to R₁₉ each independently represent a hydrogen atom or a deuterium atom;
L represents a substituted or unsubstituted arylene group having 5 to 40 carbon atoms; and
n represents an integer from 0 to 3.)

Examples of alkyl groups, cycloalkyl groups, alkyloxy groups, cycloalkyloxy groups, and polyether groups represented by R₁ and R₂ may include the following groups.

### Alkyl Groups (Carbon Atoms: 1 to 8):

Methyl group, ethyl group, n-propyl group, isopropyl group, n-butyl group, isobutyl group, tert-butyl group, n-pentyl group, isopentyl group, neopentyl group, n-hexyl group, isohexyl group, neohexyl group, n-heptyl group, isoheptyl group, neoheptyl group, n-octyl group, isooctyl group, neooctyl group, etc.

### Alkyloxy Groups (Carbon Atoms: 1 to 8):

Methyloxy group, ethyloxy group, n-propyloxy group, isopropyloxy group, n-butyloxy group, tert-butyloxy group, n-pentyloxy group, n-hexyloxy group, n-heptyloxy group, n-octyloxy group, etc.

### Cycloalkyl Groups (Carbon Atoms: 5 to 10):

Cyclopentyl group, cyclohexyl group, 1-adamantyl group, 2-adamantyl group, etc.

### Cycloalkyloxy Groups (Carbon Atoms: 5 to 10):

Cyclopentyloxy group, cyclohexyloxy group, cycloheptyloxy group, cyclooctyloxy group, 1-adamantyloxy group, 2-adamantyloxy group, etc.

### Polyether Groups:

n-1,3-Dioxabutyl group, n-2,4-dioxapentyl group, n-1,3,5-trioxahexyl group, n-2,4,6-trioxaheptyl group, n-1,3,5,7-tetraoxaoctyl group, n-2,4,6,8-tetraoxanonane group, etc.

To improve solubility, it is preferable that R₁ and R₂ are each an alkyl group, an alkyloxy group or a polyether group, each having 1 to 8 carbon atoms, and most preferably an alkyl group having 1 to 8 carbon atoms in terms of synthesis.

X represents an oxygen atom or a sulfur atom. In the present invention, from the viewpoint of hole injection and mobility properties, it is preferable that X is an oxygen atom.

Examples of alkyl groups, cycloalkyl groups, alkyloxy groups, cycloalkyloxy groups, and polyether groups represented by R₃ to Ru may include the same groups as those described for R₁ and R₂. Examples of alkenyl groups, aryloxy groups, aryl groups, and heteroaryl groups may include the following groups.

### Alkenyl Groups (Carbon Atoms: 2 to 6):

Vinyl group, allyl group, isopropenyl group, 2-butenyl group, etc.

### Aryloxy Groups:

Phenyloxy group, tolyloxy group, naphthyloxy group, etc.

### Aryl Groups:

Phenyl group, naphthyl group, anthracenyl group, phenanthrenyl group, fluorenyl group, indenyl group, pyrenyl group, perylenyl group, fluoranthenyl group, etc.

### Heteroaryl Groups:

Pyridinyl group, pyrimidinyl group, triazinyl group, furyl group, pyrrolyl group, thienyl group, quinolyl group, isoquinolyl group, benzofuranyl group, benzothienyl group, indolyl group, carbazolyl group, indenocarbazolyl group, benzooxazolyl group, benzothiazolyl group, quinoxalinyl group, benzoimidazolyl group, pyrazolyl group, dibenzofuranyl group, dibenzothienyl group, naphthyridinyl group, phenanthrolinyl group, acridinyl group, carbolinyl group, etc.

It is preferable that R₃ to R₁₁ are each an aryl group, a hydrogen atom, or a deuterium atom, and most preferably a hydrogen atom in terms of synthesis.

Examples of alkyl groups, polyether groups, cycloalkyl groups, alkyloxy groups, cycloalkyloxy groups, alkenyl groups, and aryloxy groups represented by R₁₂ and R₁₆ may include the same groups as those described for R₁, R₂, and R₃ to R₁₁.

It is preferable that R₁₂ and R₁₆ are each a hydrogen atom or a deuterium atom, and most preferably a hydrogen atom in terms of synthesis.

Also, it is preferable that R₁₃ to R₁₅ and R₁₇ to R₁₉ are each a hydrogen atom or a deuterium atom, and most preferably a hydrogen atom in terms of synthesis.

That is, it is most preferable that R₁₂ to R₁₉ are each a hydrogen atom.

Examples of substituents that may substitute the aforementioned alkyl groups, cycloalkyl groups, alkyloxy groups, cycloalkyloxy groups, polyether groups, alkenyl groups, aryloxy groups, aryl groups, and heteroaryl groups may include the following groups, in addition to deuterium atoms, cyano groups, nitro groups, etc.:
halogen atoms, such as fluorine, chlorine, bromine, and iodine;
alkyl groups, particularly groups having 1 to 8 carbon atoms, such as the methyl group, ethyl group, n-propyl group, isopropyl group, n-butyl group, isobutyl group, tert-butyl group, n-pentyl group, isopentyl group, neopentyl group, n-hexyl group, isohexyl group, neohexyl group, n-heptyl group, isoheptyl group, neoheptyl group, n-octyl group, isooctyl group, neooctyl group, etc.;
alkyloxy groups, particularly groups having 1 to 8 carbon atoms, such as the methyloxy group, ethyloxy group, propyloxy group, etc.
alkenyl groups, such as the vinyl group, allyl group, etc.;
aryloxy groups, such as the phenyloxy group, tolyloxy group, naphthyloxy group, etc.;
aryl groups, such as the phenyl group, biphenylyl group, terphenylyl group, naphthyl group, anthracenyl group, phenanthrenyl group, fluorenyl group, indenyl group, pyrenyl group, perylenyl group, fluoranthenyl group, triphenylenyl group, etc.;
heteroaryl groups, such as the pyridinyl group, pyrimidinyl group, triazinyl group, thienyl group, furyl group, pyrrolyl group, quinolyl group, isoquinolyl group, benzofuranyl group, benzothienyl group, indolyl group, carbazolyl group, indenocarbazolyl group, benzooxazolyl group, benzothiazolyl group, quinoxalinyl group, benzoimidazolyl group, pyrazolyl group, dibenzofuranyl group, dibenzothienyl group, carbolinyl group, etc.;
arylvinyl groups, such as the styryl group, naphthylvinyl group, etc.; and
acyl groups, such as the acetyl group, benzoyl group, etc.

These substituents may further include any of the substituents given as examples above.

Further, it is preferable that these substituents are each present independently, but the substituents may be bonded to each other via a single bond, a methylene group optionally having a substituent, an oxygen atom, or a sulfur atom, to form a ring.

For example, the aforementioned aryl groups and heteroaryl groups may have a phenyl group as a substituent, and this phenyl group may further have a phenyl group as a substituent. Stated differently, taking an aryl group as an example, the aryl group may be a biphenylyl group, a terphenylyl group, or a triphenylenyl group.

L represents a divalent arylene group. Examples of the arylene group may include the following groups.

### Arylene Groups:

Phenylene group, naphthalenediyl group, phenanthrenediyl group, fluorenediyl group, indenediyl group, pyrenediyl group, etc.

In the present invention, from the viewpoint of hole injection and mobility properties, it is preferable that L is a phenylene group.

From the viewpoint of synthesis, n is preferably an integer from 0 to 2, more preferably 0 or 1.

Further, L may have a substituent. Examples of the substituent may include the following groups, in addition to deuterium atoms, cyano groups, nitro groups, etc.:
halogen atoms, such as fluorine, chlorine, bromine, and iodine;
alkyl groups, particularly groups having 1 to 8 carbon atoms, such as the methyl group, ethyl group, n-propyl group, isopropyl group, n-butyl group, isobutyl group, tert-butyl group, n-pentyl group, isopentyl group, neopentyl group, n-hexyl group, isohexyl group, neohexyl group, n-heptyl group, isoheptyl group, neoheptyl group, n-octyl group, isooctyl group, neooctyl group, etc.;
alkyloxy groups, particularly groups having 1 to 8 carbon atoms, such as the methyloxy group, ethyloxy group, propyloxy group, etc.;
alkenyl groups, such as the vinyl group, allyl group, etc.;
aryloxy groups, such as the phenyloxy group, tolyloxy group, naphthyloxy group, etc.;
aryl groups, such as the phenyl group, biphenylyl group, terphenylyl group, naphthyl group, anthracenyl group, phenanthrenyl group, fluorenyl group, indenyl group, pyrenyl group, perylenyl group, fluoranthenyl group, triphenylenyl group, etc.;
heteroaryl groups, such as the pyridinyl group, pyrimidinyl group, triazinyl group, thienyl group, furyl group, pyrrolyl group, quinolyl group, isoquinolyl group, benzofuranyl group, benzothienyl group, indolyl group, carbazolyl group, indenocarbazolyl group, benzooxazolyl group, benzothiazolyl group, quinoxalinyl group, benzoimidazolyl group, pyrazolyl group, dibenzofuranyl group, dibenzothienyl group, carbolinyl group, etc.;
arylvinyl groups, such as the styryl group, naphthylvinyl group, etc.; and
acyl groups, such as the acetyl group, benzoyl group, etc.

These substituents may further include any of the substituents given as examples above. Further, it is preferable that these substituents are each present independently, but the substituents may be bonded to each other via a single bond, a methylene group optionally having a substituent, an oxygen atom, or a sulfur atom, to form a ring.

### <<Average Molecular Weight>>

As already described above, the high molecular weight compound of the present invention including, as a repeating unit, a triarylamine structural unit represented by the aforementioned general formula (1) has excellent properties, such as hole injection properties, hole mobility, electron blockability, thin-film stability, heat resistance, etc., but from the viewpoint of further improving these properties and ensuring film formability, it is preferable that, for example, the weight-average molecular weight in terms of polystyrene as measured by GPC is preferably 10.000 or greater to less than 1,000,000, more preferably 10,000 or greater to less than 500,000, even more preferably within the range of 10,000 or greater to less than 200,000.

### <<Other Structural Units>>

To ensure coatability when employed for forming an organic layer in an organic EL device by e.g. coating, as well as adhesion with other layers and durability, it is preferable that the high molecular weight compound of the present invention is a copolymer including other structural unit(s) as repeating unit(s). Example of such other structural units may include a thermally cross-linkable structural unit, a triarylamine structural unit different from that represented by the general formula (1), a connecting structural unit represented by general formula (4) below, etc.

### <<<Connecting Structural Unit>>>

The high molecular weight compound of the present invention may include, as a repeating unit, a connecting structural unit represented by general formula (4) below.

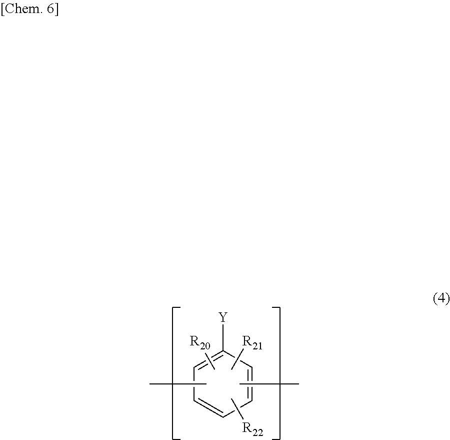

(In the formula:
R₂₀ to R₂₂ each independently represent a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, or a substituted or unsubstituted aryloxy group; and
Y represents a hydrogen atom, a deuterium atom, a substituted or unsubstituted amino group, a substituted or unsubstituted aryl group, or a substituted or unsubstituted heteroaryl group.)

Examples of alkyl groups, polyether groups, cycloalkyl groups, alkyloxy groups, cycloalkyloxy groups, alkenyl groups, and aryloxy groups represented by R₂o to R₂₂ may include the same groups as those described for R₁. R₂, and R₃ to Ru.

It is preferable that R₁₀ to R₂₂ are each a hydrogen atom or a deuterium atom, and most preferably a hydrogen atom in terms of synthesis.

Examples of aryl groups and heteroaryl groups represented by Y may include the same groups as those described as examples of aryl groups and heteroaryl groups for R₃ to Ru described above.

The amino group, aryl group, or heteroaryl group represented by Y may have a substituent similar to that in L described above. The substituent may further have a substituent similar to that in L described above.

Y is preferably a hydrogen atom, a diphenylamino group, a phenyl group, a naphthyl group, a dibenzofuranyl group, a dibenzothienyl group, a phenanthrenyl group, a fluorenyl group, a carbazolyl group, an indenocarbazolyl group, or an acridinyl group.

Concrete examples of the connecting structural units are illustrated below as chemical formulas (4aa) to (4 bp). Note that, in the chemical formulas (4aa) to (4 bp), a dotted line represents a bonding site to an adjacent structural unit, whereas a solid line with a free end extending from a ring indicates that the free end is a methyl group. The following illustrates preferable concrete examples of the connecting structural unit, but the connecting structural unit used in the present invention is not limited to these structural units.

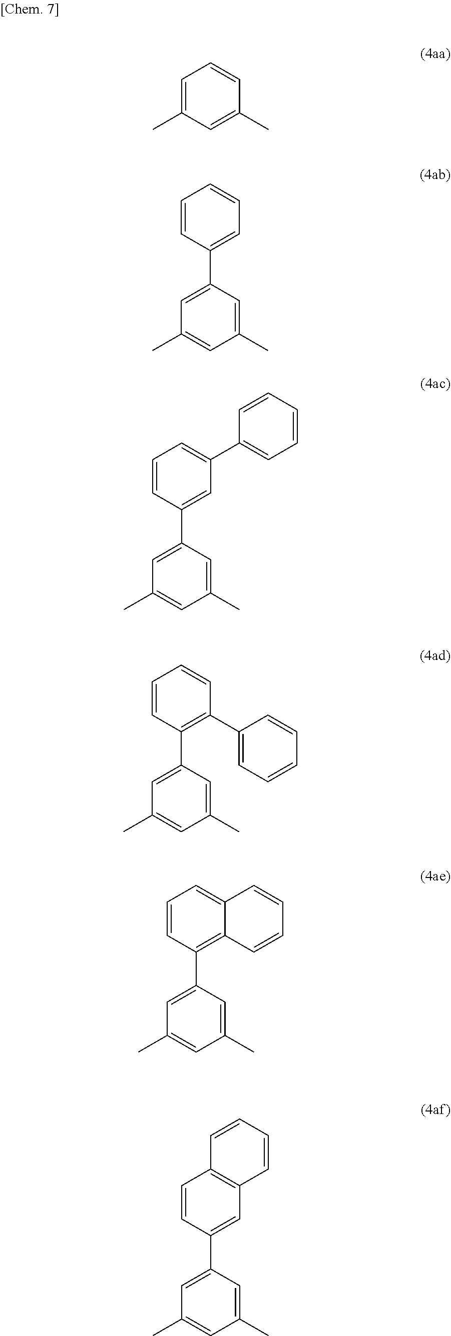

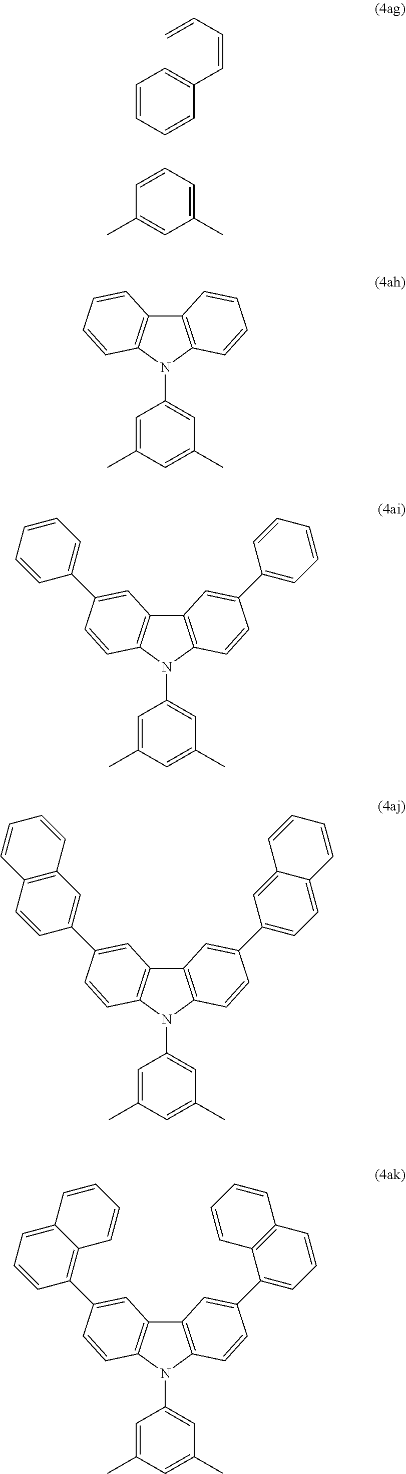

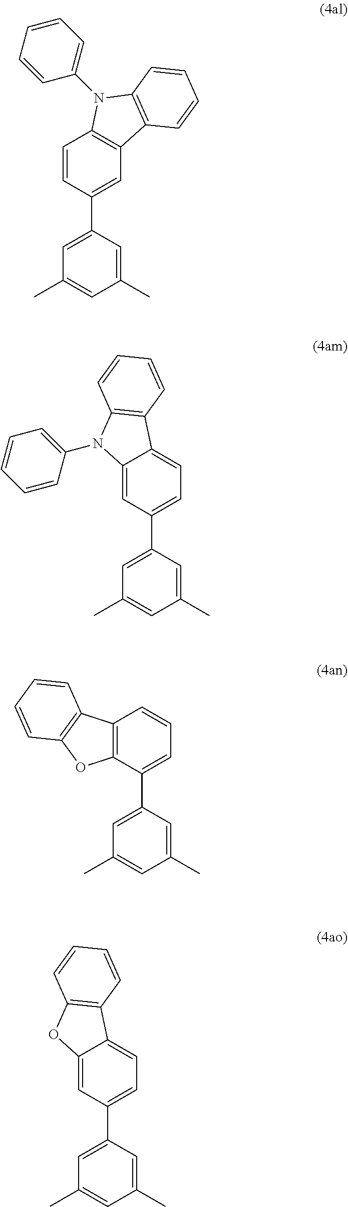

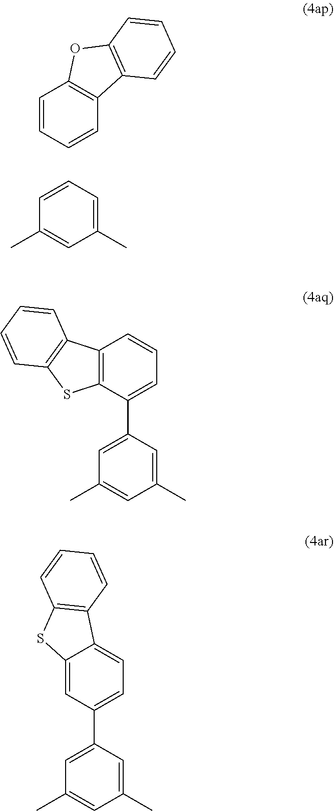

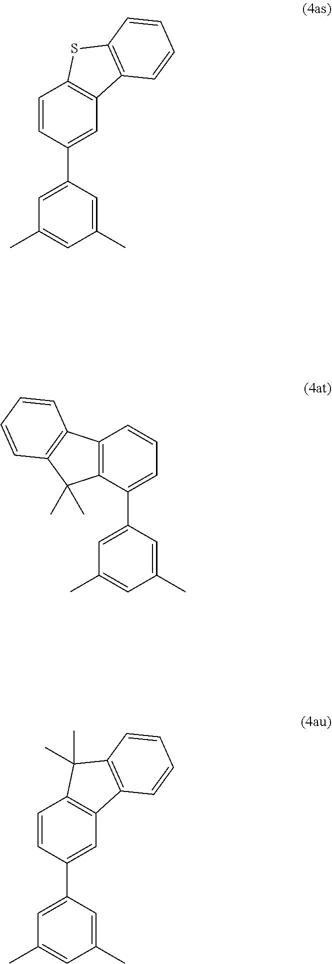

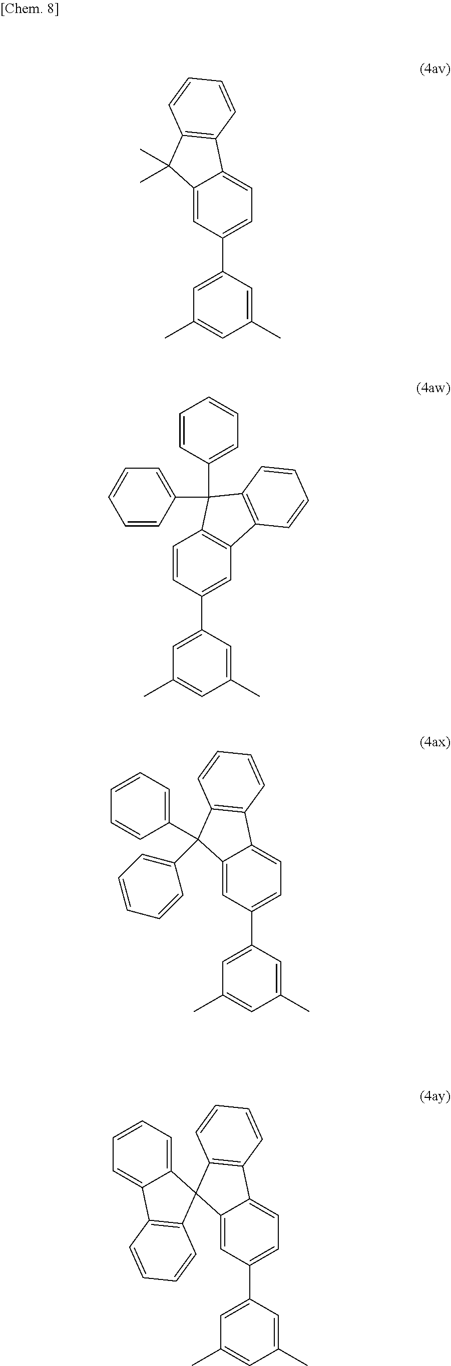

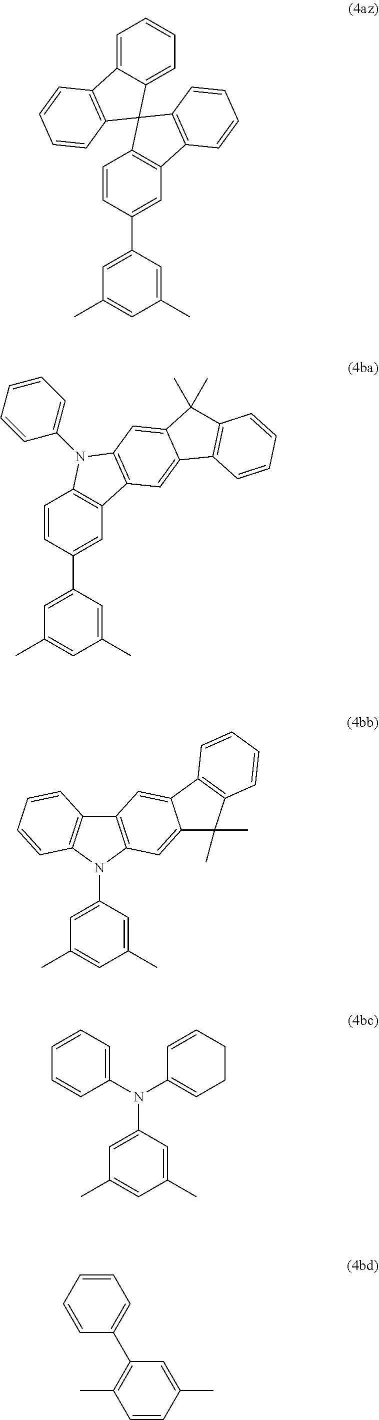

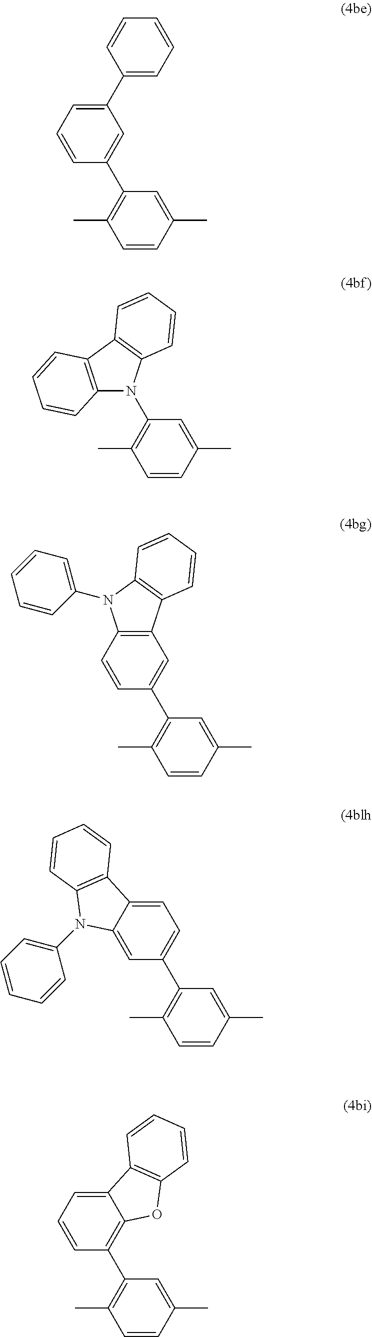

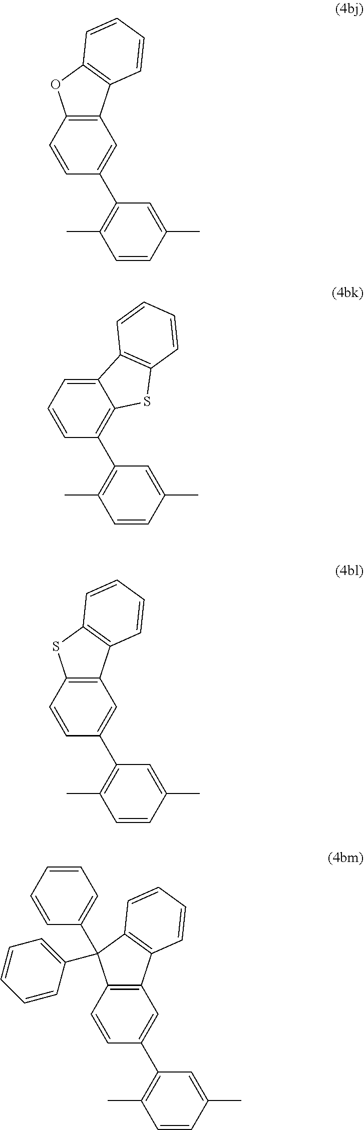

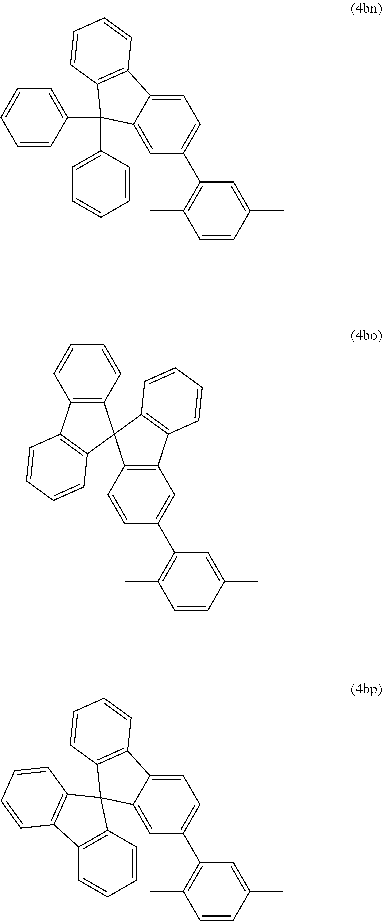

### <<<Thermally Cross-Linkable Structural Unit>>>

A thermally cross-linkable structural unit is a structural unit having a reactive functional group, such as a vinyl group, a cyclobutane ring, etc., within the structural unit. The high molecular weight compound of the present invention may include two or more types of thermally cross-linkable structural units as repeating units. Concrete examples of the thermally cross-linkable structural units are illustrated in formulas (3aa) to (3bd). The following illustrates preferable concrete examples of the thermally cross-linkable structural unit, but the thermally cross-linkable structural unit used in the present invention is not limited to these structural units.

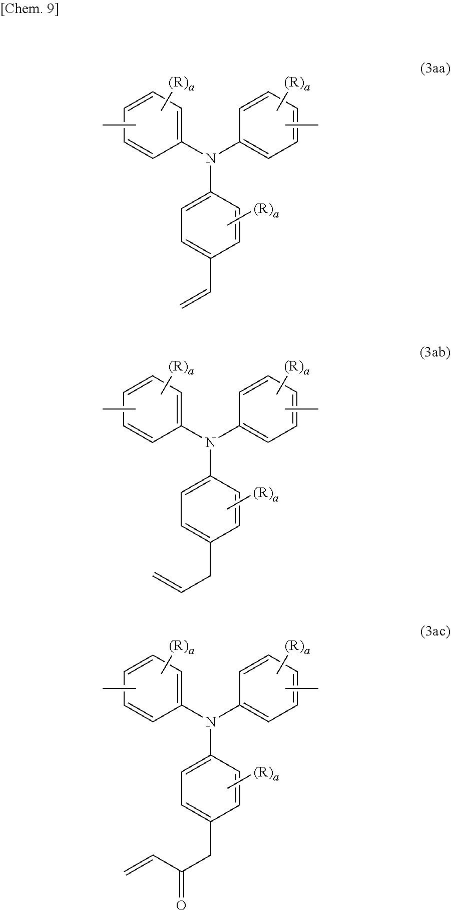

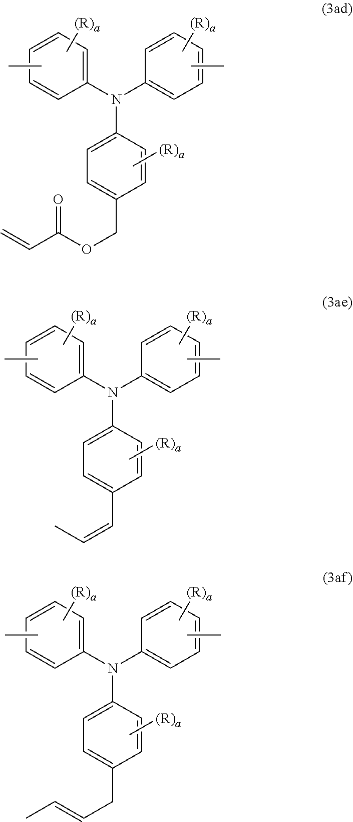

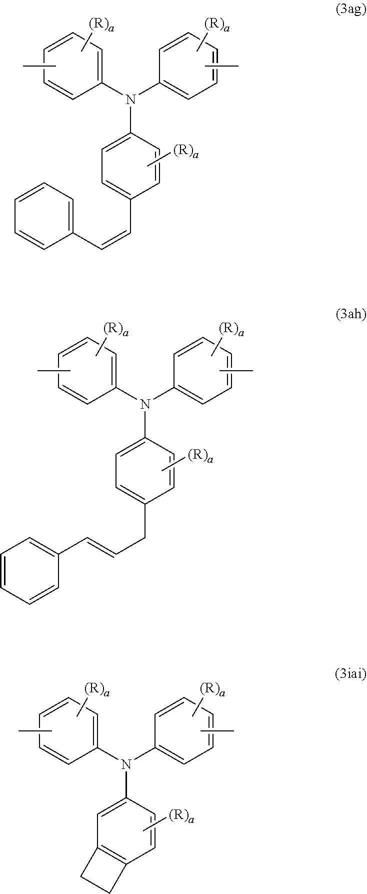

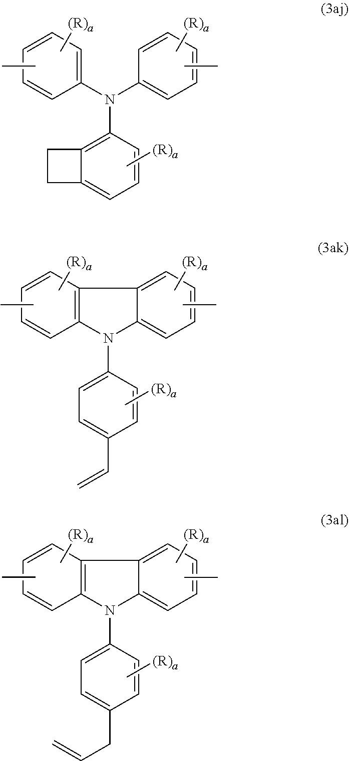

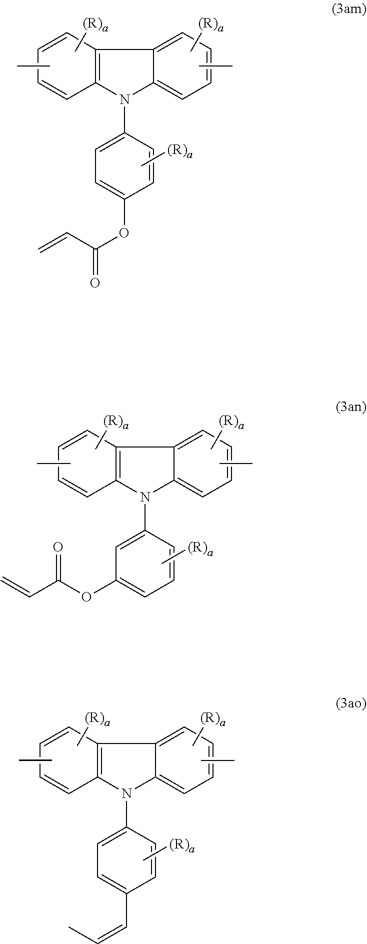

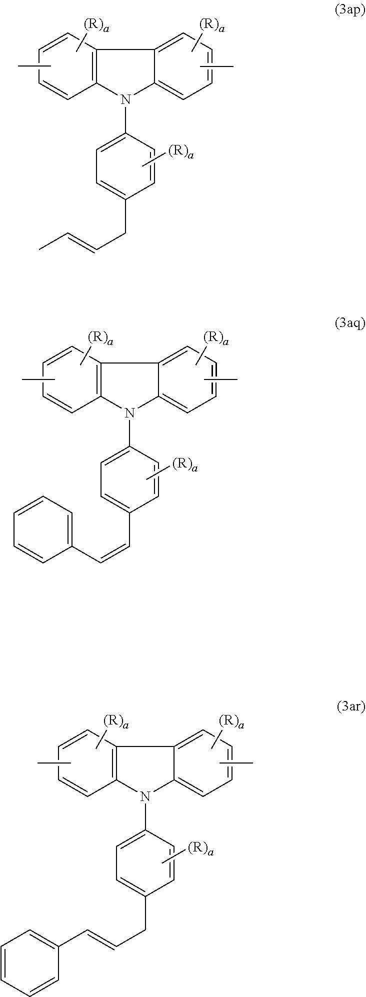

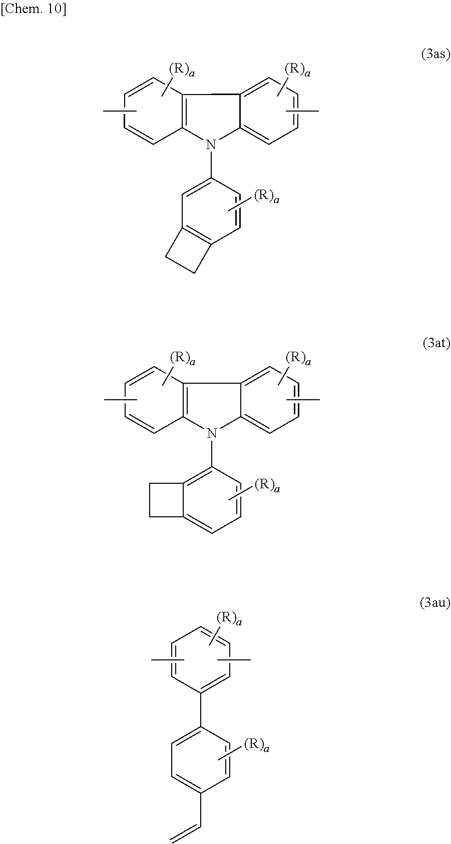

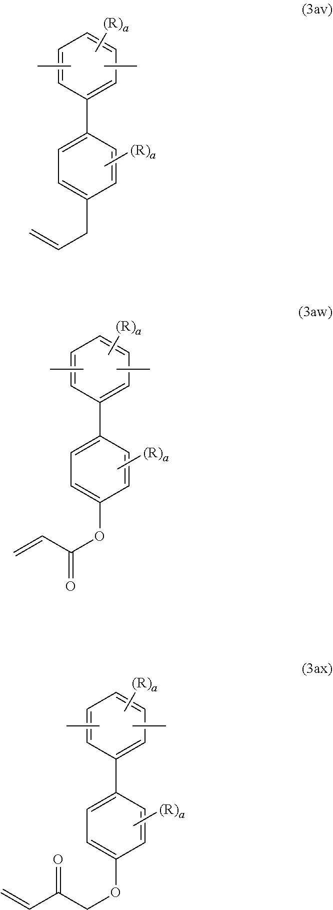

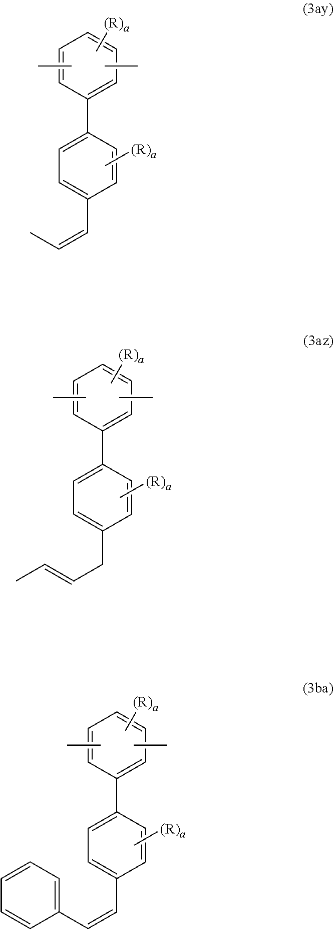

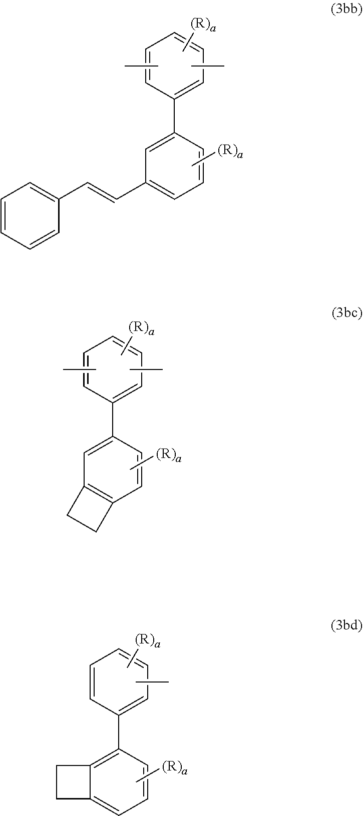

(In the formulas:

R independently represents a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, a substituted or unsubstituted aryloxy group, a substituted or unsubstituted aryl group, or a substituted or unsubstituted heteroaryl group;
a wavy line represents cis or trans;
a dotted line represents a bond to a main chain;
a represents an integer from 0 to 4; and
b represents an integer from 0 to 3.)

Note that, in the formulas (3aa) to (3bd) above, a broken line represents a bonding site to an adjacent structural unit, a wavy line represents cis or trans, and a solid line with a free end extending from a ring indicates that the free end is a methyl group.

Examples of alkyl groups, polyether groups, cycloalkyl groups, alkyloxy groups, cycloalkyloxy groups, alkenyl groups, aryloxy groups, aryl groups, and heteroaryl groups represented by R may include the same groups as those described for R₁, R₂, R₃ to Ru in general formula (1) described above.

It is preferable that R is a hydrogen atom or a deuterium atom, and most preferably a hydrogen atom in terms of synthesis.

### <<Combinations of Structural Units>>

The other structural unit, such as the thermally cross-linkable structural unit, the triarylamine structural unit different from that represented by the general formula (1), etc., may be included alone in the high molecular weight compound as a repeating unit, or may be included in the high molecular weight compound by constituting a repeating unit together with the connecting structural unit represented by general formula (4) described above.

In the high molecular weight compound of the present invention, when the structural unit represented by general formula (1) is defined as A, the connecting structural unit represented by general formula (4) is defined as B. and the thermally cross-linkable structural unit or the triarylamine structural unit different from that represented by general formula (1) is defined as C, it is preferable that the content of the structural unit A is 1 mol % or greater, particularly 20 mol % or greater. Further, on condition that the content of the structural unit A is as described above, it is preferable that the content of the structural unit B is 1 mol % or greater, particularly from 30 to 70 mol %, and the content of the structural unit C is 1 mol % or greater, particularly from 3 to 20 mol %. Further, in terms of forming an organic layer of an organic EL device, it is most preferable that the high molecular weight compound includes a terpolymer including the structural units A, B, and C in a manner satisfying the aforementioned conditions.

As for the structural units, it is preferable to include the structural units A and B, and particularly, it is preferable to include a repeating unit represented by general formula (2) below.

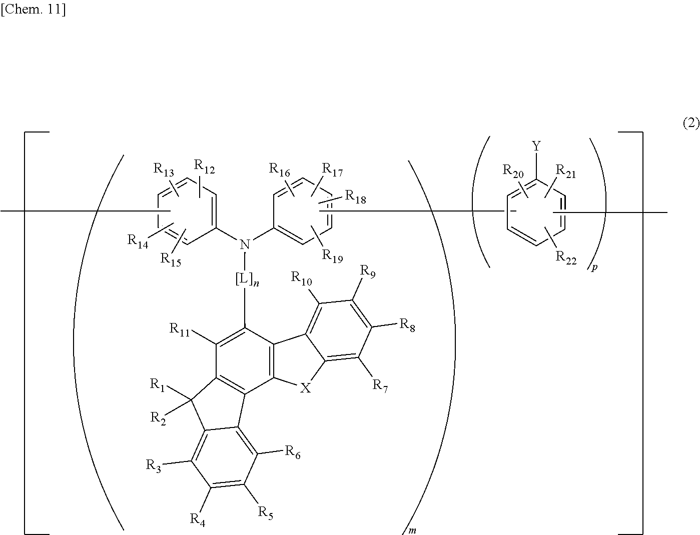

(In the formula:
R₁ to R₁₉, X, L, and n are the same as in general formula (1);
R₂₀ to R₂₂ each independently represent a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, or a substituted or unsubstituted aryloxy group;
Y represents a hydrogen atom, a deuterium atom, a substituted or unsubstituted amino group, a substituted or unsubstituted aryl group, or a substituted or unsubstituted heteroaryl group;
m and p are expressed in mole fraction;
m represents from 0.1 to 0.9; and
p represents from 0.1 to 0.9.)

The alkyl groups, polyether groups, cycloalkyl groups, alkyloxy groups, cycloalkyloxy groups, alkenyl groups, aryloxy groups, aryl groups, heteroaryl groups, and substituents in general formula (2) are the same as in the general formula (1).

### <<Synthesis Method>>

The high molecular weight compound of the present invention can be synthesized by connecting the structural units by forming C—C bonds or C—N bonds through the Suzuki polymerization reaction or the Hartwig-Buchwald polymerization reaction. More specifically, the high molecular weight compound can be synthesized by preparing unit compounds that respectively have the aforementioned structural units, and subjecting the unit compounds to boric acid esterification or halogenation as appropriate and then to a polycondensation reaction using an appropriate catalyst.

For example, a triarylamine derivative represented by general formula (1a) below can be used as a compound for introducing a structural unit represented by general formula (1).

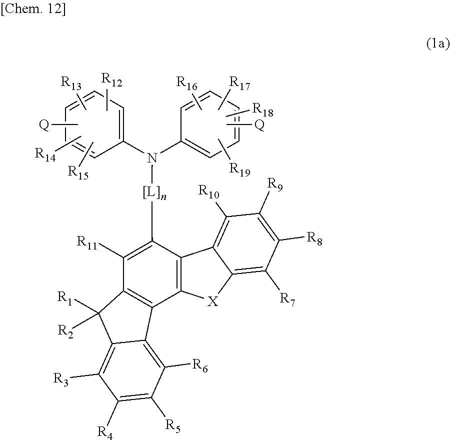

(In the formula:
Q represents a hydrogen atom, a halogen atom, or a borate ester group, and
R₁ to R₁₉, L, and n are all the same as in general formula (1).)

More specifically, the general formula (1a) above represents a unit compound for introducing a structural unit represented by general formula (1) when Q is a hydrogen atom, while it respectively represents a halide or a borate ester used for polymer synthesis when Q is a halogen atom or a borate ester group. Herein, the halide is preferably a bromide.

For example, a terpolymer including 40 mol % of a structural unit A represented by general formula (1), 50 mol % of a structural unit B represented by general formula (4), and 10 mol % of a thermally cross-linkable structural unit C (see formula (3ai) of FIG. 3) is represented by general formula (5) below.

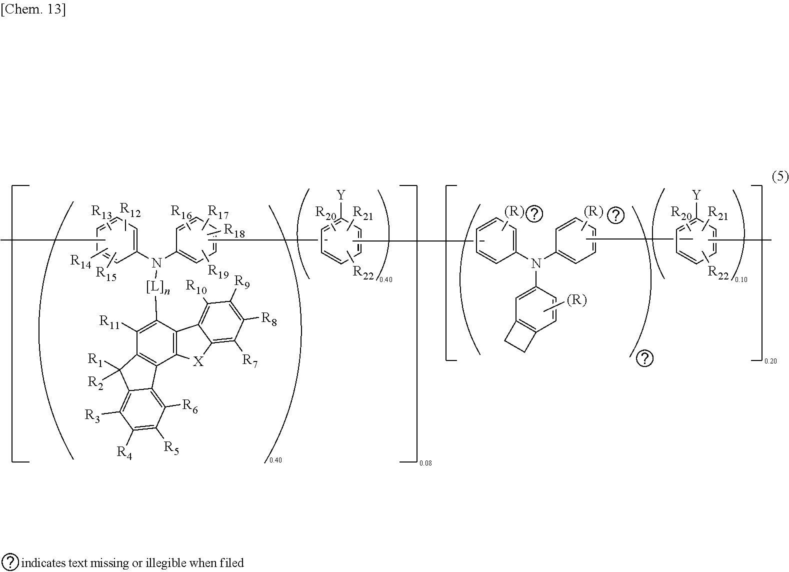

Such a copolymer can be synthesized by a polycondensation reaction between a borate ester and a halide. In this case, it is either necessary that intermediates for introducing structural unit A and structural unit C are borate esters whereas an intermediate for introducing structural unit B is a halide, or that intermediates for introducing structural unit A and structural unit C are halides whereas an intermediate for introducing structural unit B is a borate ester. That is, the molar ratio between the halides and borate esters needs to be equal.

The aforementioned high molecular weight compound of the present invention can be dissolved in an aromatic organic solvent, such as benzene, toluene, xylene, anisole, etc., to prepare a coating liquid, and the coating liquid can be coated onto a predetermined substrate and then heated and dried, to thereby form a thin film having excellent properties such as hole injectability, hole transportability, electron blockability, etc. The obtained thin film also has excellent heat resistance and excellent adhesiveness to other layers.

The high molecular weight compound of the present invention can be used as a constituent material for a hole injection layer and/or a hole transport layer of an organic EL device. A hole injection layer and a hole transport layer formed by the high molecular weight compound have higher hole injectability, greater mobility and higher electron blockability compared to layers formed by conventional materials, and can confine excitons generated within the light-emitting layer. It is also possible to achieve such advantages as increasing the probability of hole-electron recombination and achieving high luminous efficiency, as well as lowering the driving voltage and improving the organic EL device's durability.

Further, the high molecular weight compound of the present invention having the aforementioned electric properties has a wider bandgap than conventional materials and is effective for confining excitons, and can therefore be suitably used also for electron blocking layers and light-emitting layers, as a matter of course.

### <Organic EL Device>

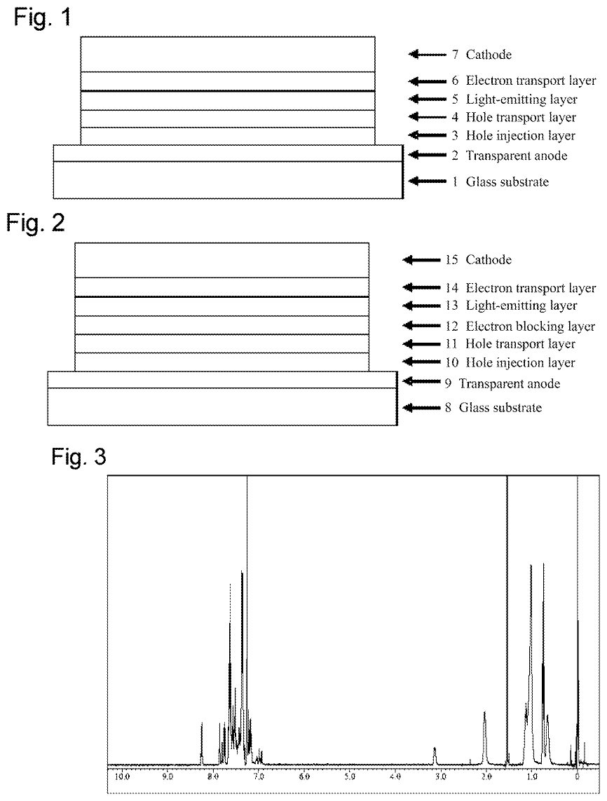

An organic EL device according to the present invention including an organic layer formed using the aforementioned high molecular weight compound of the present invention may have, for example, a structure as illustrated in FIG. 1. More specifically, a transparent anode 2, a hole injection layer 3, a hole transport layer 4, a light-emitting layer 5, an electron transport layer 6, and a cathode 7 are provided on a glass substrate 1 (or a transparent substrate such as a transparent resin substrate).

Needless to say, the organic EL device employing the high molecular weight compound is not limited to the aforementioned layer structure; for example, a hole blocking layer may be provided between the light-emitting layer 5 and the electron transport layer 6, or an electron blocking layer may be provided between a hole transport layer 11 and a light-emitting layer 13 as in the structure illustrated in FIG. 2. Further, although not illustrated in FIG. 2, an electron injection layer may be provided between a cathode 15 and an electron transport layer 14. Also, some layers may be omitted. For example, in the structure illustrated in FIG. 1, the hole injection layer 3 may be omitted, to create a simple layer structure in which an anode 2, a hole transport layer 4, a light-emitting layer 5, an electron transport layer 6, and a cathode 7 are provided on a glass substrate 1. Moreover, a two-layer structure, created by stacking two layers having the same functionality, is also possible.

By making use of such properties as hole injectability, hole transportability, etc., the high molecular weight compound can suitably be used as a material for forming an organic layer (for example, a hole injection layer 3, a hole transport layer 4, a light-emitting layer 5, or an electron blocking layer) provided between the aforementioned anode 2 and cathode 7.

In the organic EL device, the transparent anode 2 may be formed by a known electrode material, and may be formed by evaporatively depositing an electrode material having a large work function, such as ITO, gold, etc., onto a glass substrate 1 (or a transparent substrate such as a transparent resin substrate).

The hole injection layer 3 provided on the transparent anode 2 can be formed, for example, by using a coating liquid in which the high molecular weight compound of the present invention is dissolved in an aromatic organic solvent such as toluene, xylene, anisole, etc. More specifically, this coating liquid can be coated onto the transparent anode 2 by spin coating, ink-jetting, etc.

Further, in the organic EL device including an organic layer formed using the aforementioned high molecular weight compound, the hole injection layer 3 may be formed by using a conventionally known material, such as one or more of the following materials, without using the aforementioned high molecular weight compound:
porphyrin compounds typified by copper phthalocyanine;
starburst-type triphenylamine derivatives;
arylamines (for example, triphenylamine trimer and tetramer) having a structure connected by a single bond or a divalent group that does not include a hetero atom;
acceptor heterocyclic compounds such as hexacyanoazatriphenylene; and
coating-type high molecular weight materials, such as poly(3,4-ethylene dioxythiophene) (PEDOT), poly(styrene sulfonate) (PSS), etc.

Formation of the hole injection layer 3 (thin film) using such materials can be achieved, for example, by vapor deposition or by coating, such as spin coating, ink-jetting, etc., depending on the type of film-forming material. Thin-film formation is the same for the other layers, which is conducted by vapor deposition or coating, depending on the type of film-forming material.

Like the hole injection layer 3, the hole transport layer 4 provided on the hole injection layer 3 can be formed by coating, such as spin coating, ink-jetting, etc., using the high molecular weight compound of the present invention.

In the organic EL device of the present invention including an organic layer formed using the aforementioned high molecular weight compound, the hole transport layer 4 can be formed by using a conventionally known hole-transporting material. Typical examples of such hole-transporting materials may include the following.

Benzidine derivatives, such as:
N,N′-diphenyl-N,N′-di(m-tolyl)benzidine (abbreviated hereinbelow as “TPD”);
N,N′-diphenyl-N,N′-di(α-naphthyl)benzidine (abbreviated hereinbelow as “NPD”); and
N,N,N′,N′-tetrabiphenylylbenzidine.

Amine-based derivatives, such as:
1,1-bis[4-(di-4-tolylamino)phenyl]cyclohexane (abbreviated hereinbelow as “TAPC”); and
various triphenylamine trimers and tetramers.

Coating-type high molecular weight materials that may also be used for hole injection layers.

The aforementioned compound(s), including the high molecular weight compound, to be used for the hole transport layer 4 may be formed into a film singly, or two or more types may be mixed and formed into a film. One or more types of the aforementioned compounds may be used to form a plurality of layers, and a multilayer film formed by stacking such layers may constitute the hole transport layer 4.

Further, in the organic EL device including an organic layer formed using the aforementioned high molecular weight compound, a single layer may serve as both the hole injection layer 3 and the hole transport layer 4. Such a hole injection-transport layer can be formed by coating using a polymer material such as PEDOT etc.

In the hole transport layer 4 (same for the hole injection layer 3), it is possible to use, for example, a material ordinarily used for such layers and p-doped with trisbromophenylamine hexachloroantimonate or a radialene derivative (see, for example, WO2014/009310). The hole transport layer 4 (same for the hole injection layer 3) may be formed by using a polymer compound having a TPD basic skeleton.

Furthermore, the electron blocking laver 12 (which can be provided between the hole transport layer 11 and the light-emitting layer 13 as illustrated in FIG. 2) can be formed by coating, such as spin coating, ink-jetting, etc., by using the high molecular weight compound of the present invention.

Further, in the organic EL device including an organic layer formed using the aforementioned high molecular weight compound, the electron blocking layer 12 can be formed by using a known electron blocking compound having electron blockability, such as a carbazole derivative or a compound having a triphenylsilyl group and a triarylamine structure. Concrete examples of carbazole derivatives and compounds having a triarylamine structure may include the following.

Examples of carbazole derivatives:
4,4′,4″-tri(N-carbazolyl)triphenylamine (abbreviated hereinbelow as “TCTA”);
9,9-bis[4-(carbazol-9-yl)phenyl]fluorene;
1,3-bis(carbazol-9-yl)benzene (abbreviated hereinbelow as “mCP”); and
2,2-bis(4-carbazol-9-ylphenyl)adamantane (abbreviated hereinbelow as “Ad-Cz”).

Example of compound having triarylamine structure:
9-[4-(carbazol-9-yl)phenyl]-9-[4-(triphenylsilyl)phenyl]-9H-fluorene.

The aforementioned compound(s), including the high molecular weight compound of the present invention, to be used for the electron blocking layer 12 may be formed into a film singly, or two or more types may be mixed and formed into a film. One or more types of the aforementioned compounds may be used to form a plurality of layers, and a multilayer film formed by stacking such layers may constitute the electron blocking layer 12.

In the organic EL device including an organic layer formed using the aforementioned high molecular weight compound, the light-emitting layer 5 can be formed by using a light-emitting material, with examples including metal complexes of quinolinol derivatives, such as Alq₃, as well as various other metal complexes of zinc, beryllium, aluminum, etc., anthracene derivatives, bisstyrylbenzene derivatives, pyrene derivatives, oxazole derivatives, poly(para-phenylene vinylene) derivatives, etc.

Further, the light-emitting layer 5 may be constituted by a host material and a dopant material. In this case, for the host material, it is possible to use, for example, a thiazole derivative, a benzimidazole derivative, a polydialkylfluorene derivative, etc., in addition to the aforementioned light-emitting material. Furthermore, it is possible to use the aforementioned high molecular weight compound of the present invention. For the dopant material, it is possible to use, for example, quinacridone, coumarin, rubrene, perylene, a derivative of the above, a benzopyran derivative, a rhodamine derivative, an aminostyryl derivative, etc.

The aforementioned compound(s), including the high molecular weight compound of the present invention, to be used for the light-emitting layer 5 may be formed into a film singly, or two or more types may be mixed and formed into a film. One or more types of the aforementioned compounds may be used to form a plurality of layers, and a multilayer film formed by stacking such layers may constitute the light-emitting layer 5.

Furthermore, the light-emitting layer 5 may be formed by using a phosphorescent material as a light-emitting material. For the phosphorescent material, it is possible to use, for example, a phosphorescent substance such as a metal complex of iridium, platinum, etc. Usable examples may include green phosphorescent substances such as Ir(ppy)₃ etc., blue phosphorescent substances such as FIrpic, FIr6, etc., and red phosphorescent substances such as Btp₂Ir(acac) etc. These phosphorescent materials are used by being doped in a hole-injecting/transporting host material or an electron-transporting host material.

It should be noted that, to avoid concentration quenching, doping of the host material(s) with a phosphorescent material is preferably performed by co-vapor deposition within a range of 1 to 30 wt % with respect to the entire light-emitting layer.

Further, for the light-emitting material, it is possible to use, for example, a material emitting delayed fluorescence, e.g., PIC-TRZ, CC2TA, PXZ-TRZ, a CDCB derivative such as 4CzIPN, etc. (see Appl. Phys. Let., 98, 083302 (2011)).

By forming the light-emitting layer 5 by making the high molecular weight compound support a dopant, e.g., a fluorescent substance, a phosphorescent substance, or a material emitting delayed fluorescence, it is possible to achieve an organic EL device that is reduced in driving voltage and improved in luminous efficiency.

In the organic EL device including an organic layer formed using the aforementioned high molecular weight compound, for the hole-injecting/transporting host material, it is possible to use the high molecular weight compound of the present invention. Other than this, it is also possible to use, for example, a carbazole derivative, such as 4,4′-di(N-carbazolyl)biphenyl (abbreviated hereinbelow as “CBP”), TCTA, mCP, etc.

Further, in the organic EL device including an organic layer formed using the aforementioned high molecular weight compound, for the electron-transporting host material, it is possible to use, for example, p-bis(triphenylsilyl)benzene (abbreviated hereinbelow as “UGH2”), 2,2′,2″-(1,3,5-phenylene)-tris(1-phenyl-1H-benzimidazole) (abbreviated hereinbelow as “TPBI”), etc.

In the organic EL device including an organic layer formed using the aforementioned high molecular weight compound, a hole blocking layer (not illustrated) to be provided between the light-emitting layer 5 and the electron transport layer 6 can be formed by using a known compound having hole blockability. Examples of known compounds having hole blockability may include the following:
phenanthroline derivatives, such as bathocuproine (abbreviated hereinbelow as “BCP”);
metal complexes of quinolinol derivatives, such as bis(2-methyl-8-quinolinato))-4-phenylphenolato aluminum (III) (abbreviated hereinbelow as “BAlq”);
various rare-earth complexes;
triazole derivatives;
triazine derivatives; and
oxadiazole derivatives, etc.

These materials can be used also for forming the electron transport layer 6 described below, and can also be used for forming a hole blocking layer-cum-electron transport layer 6.

The aforementioned compound(s) to be used for the hole blocking layer may be formed into a film singly, or two or more types may be mixed and formed into a film. One or more types of the aforementioned compounds may be used to form a plurality of layers, and a multilayer film formed by stacking such layers may constitute the hole blocking layer.

In the organic EL device including an organic layer formed using the aforementioned high molecular weight compound, the electron transport layer 6 can be formed by using a known electron-transporting compound, with examples including metal complexes of quinolinol derivatives, such as Alq₃, BAlq, etc., as well as various other metal complexes, pyridine derivatives, pyrimidine derivatives, triazole derivatives, triazine derivatives, oxadiazole derivatives, thiadiazole derivatives, carbodiimide derivatives, quinoxaline derivatives, phenanthroline derivatives, silole derivatives, benzoimidazole derivatives, etc.

The aforementioned compound(s) to be used for the electron transport layer 6 may be formed into a film singly, or two or more types may be mixed and formed into a film. One or more types of the aforementioned compounds may be used to form a plurality of layers, and a multilayer film formed by stacking such layers may constitute the hole blocking layer.

Further, in the organic EL device including an organic layer formed using the aforementioned high molecular weight compound, an electron injection layer (not illustrated) to be provided as necessary may be formed by a known compound, with examples including alkali metal salts such as lithium fluoride, cesium fluoride, etc., alkaline-earth metal salts such as magnesium fluoride etc., metal oxides such as aluminum oxide etc., and organic metal complexes such as lithium quinolate etc.

For the cathode 7 of the organic EL device including an organic layer formed using the aforementioned high molecular weight compound, an electrode material having a low work function, such as aluminum etc., or an alloy having an even lower work function, such as magnesium silver alloy, magnesium indium alloy, aluminum magnesium alloy, etc., may be used as an electrode material.

As described above, by forming at least one of the hole injection layer, the hole transport layer, the light-emitting layer, and the electron blocking layer by using the high molecular weight compound of the present invention, it is possible to achieve an organic EL device having high luminous efficiency and power efficiency, low practical driving voltage, low emission start voltage, and extremely good durability. Particularly, this organic EL device is reduced in driving voltage and improved in current resistance, and thereby improved in maximum light emission luminance, while having high luminous efficiency.

### EXAMPLES

The present invention will be described below according to the following experimental examples, but the present invention is not limited by the following examples.

In the following description, a structural unit, within the high molecular weight compound of the present invention, represented by general formula (1) is described as “structural unit A”, a connecting structural unit represented by general formula (4) is described as “structural unit B”, a thermally cross-linkable structural unit is described as “structural unit C”, and a structural unit constituted by a triarylamine that is not represented by general formula (1) is described as “structural unit D”.

Purification of synthesized compounds was conducted by column chromatography purification or crystallization using a solvent. Compound identification was conducted by NMR analysis.

In order to produce high molecular weight compounds, the following Intermediates 1 to 14 were synthesized.

### Synthesis of Intermediate 1

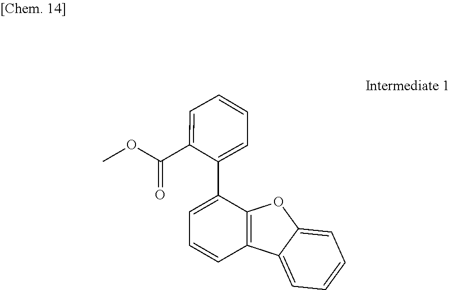 [SMILES: COC(=O)c1ccccc1-c1cccc2c1oc1ccccc12]

The following components were placed in a nitrogen-purged reaction vessel, and aerated with nitrogen gas for 30 minutes.
Methyl 2-bromobenzoate: 25.0 g
Dibenzofuran-4-boronic acid: 27.1 g
Potassium carbonate: 32.1 g
Toluene: 200 mL
Ethanol: 100 mL
Water: 75 mL

Next, 1.3 g of tetrakis(triphenylphosphine)palladium(0) was added and heated, and the mixture was stirred at 78° C. for 6 hours. After the mixture was cooled to room temperature, water and toluene were added, and the organic layer was collected by liquid separation. The organic layer was dehydrated with anhydrous sodium sulfate, then subjected to adsorption purification using 175 g of silica gel, and thereafter concentrated under reduced pressure, to obtain 32.8 g of a pale-yellow oil of Intermediate 1 (yield: 93.2%).

### Synthesis of Intermediate 2

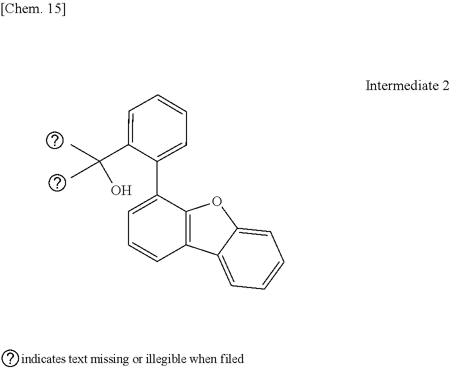 [SMILES: CC(C)(O)c1ccccc1-c1cccc2c1oc1ccccc12]

The following components were placed in a nitrogen-purged reaction vessel, and were cooled to 0° C.
Intermediate 1: 25.4 g
THF: 245 mL

Next, 100 mL of a 2 M diethyl ether solution of n-octylmagnesium bromide was dropped slowly, and the temperature was raised to room temperature. The mixture was stirred for a total of 27 hours, and then a 10 wt % aqueous solution of ammonium chloride and toluene were added, and the organic layer was collected by liquid separation. The organic layer was dehydrated with anhydrous sodium sulfate and thereafter concentrated under reduced pressure, to obtain a crude product. The crude product was purified by column chromatography (n-hexane/chloroform), to obtain 11.4 g of a white solid of Intermediate 2 (yield: 28.3%).

### Synthesis of Intermediate 3

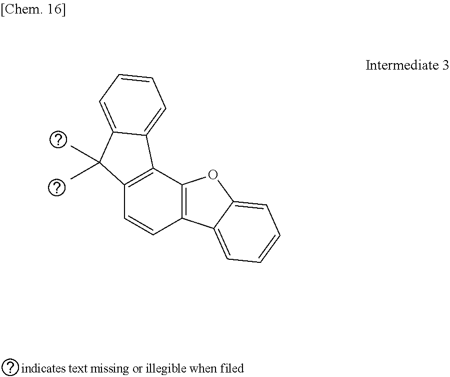 [SMILES: CC1(C)c2ccccc2-c2c1ccc1c2oc2ccccc21]

The following components were placed in a nitrogen-purged reaction vessel, and were cooled to −65° C.
Intermediate 2: 12.8 g
Dichloromethane: 130 mL

Next, 4.0 g of boron trifluoride diethyl ether complex was added and the temperature was slowly raised to room temperature, and the mixture was stirred for a total of 8 hours. A saturated aqueous solution of sodium hydrogen carbonate was added slowly, and the organic layer was collected by liquid separation. The organic layer was dehydrated with anhydrous sodium sulfate and thereafter concentrated under reduced pressure, to obtain a crude product. The crude product was purified by column chromatography (n-hexane), to obtain 11.9 g of a colorless oil of Intermediate 3 (yield: 96.4%).

### Synthesis of Intermediate 4

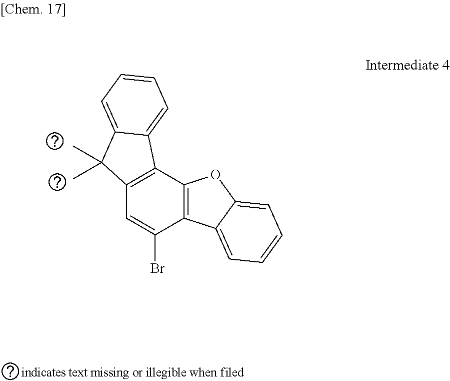 [SMILES: CC1(C)c2ccccc2-c2c1cc(Br)c1c2oc2ccccc21]

The following components were placed in a nitrogen-purged reaction vessel, and were cooled to 0° C.
Intermediate 3: 11.8 g
Dichloromethane: 120 mL

Next, 1.3 mL of bromine was added, and the mixture was stirred for 7 hours. A 10 wt % aqueous solution of sodium thiosulfate was added, and the organic layer was collected by liquid separation. The organic layer was dehydrated with anhydrous sodium sulfate and thereafter concentrated under reduced pressure, to obtain 13.1 g of a white solid of Intermediate 4 (yield: 95.3%).

### Synthesis of Intermediate 5

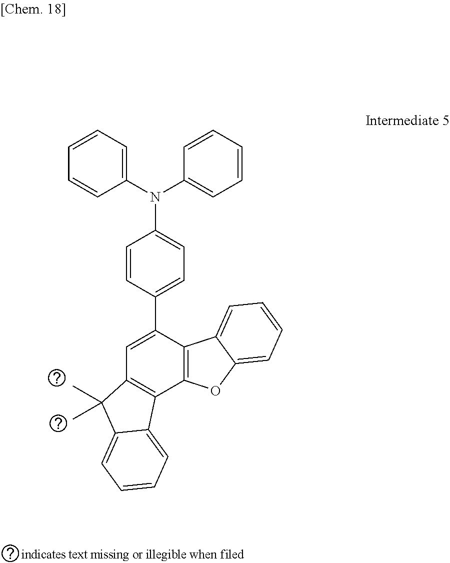 [SMILES: CC1(C)c2ccccc2-c2c1cc(-c1ccc(N(c3ccccc3)c3ccccc3)cc1)c1c2oc2ccccc21]

The following components were placed in a nitrogen-purged reaction vessel, and aerated with nitrogen gas for 30 minutes.
Intermediate 4: 12.9 g
Triphenylamine-4-boronic acid pinacol ester: 9.4 g
2 M aqueous solution of potassium carbonate: 18 mL
Toluene: 57 mL
Ethanol: 14 mL

Next, 0.27 g of tetrakis(triphenylphosphine)palladium(0) was added and heated, and the mixture was stirred under reflux for 16 hours. After the mixture was cooled to room temperature, water and toluene were added, and the organic layer was collected by liquid separation. The organic layer was dehydrated with anhydrous sodium sulfate and thereafter concentrated under reduced pressure, to obtain a crude product. The crude product was purified by column chromatography (n-hexane/toluene), to obtain 17.8 g of a colorless oil of Intermediate 5 (yield: 106%).

### Synthesis of Intermediate 6

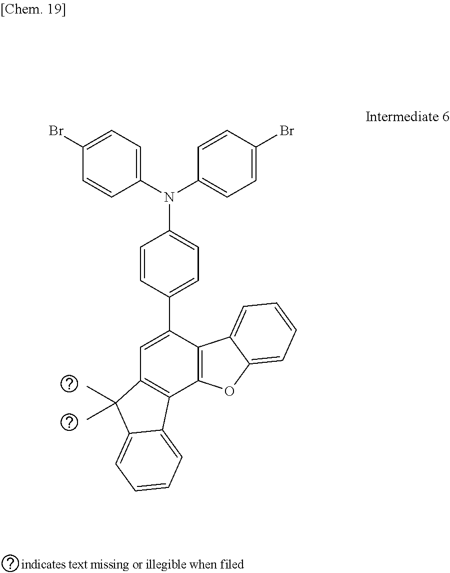 [SMILES: CC1(C)c2ccccc2-c2c1cc(-c1ccc(N(c3ccc(Br)cc3)c3ccc(Br)cc3)cc1)c1c2oc2ccccc21]

The following components were placed in a nitrogen-purged reaction vessel.
Intermediate 5: 16.0 g
THF: 160 mL

Next, 7.9 mg of N-bromosuccinimide was added, and the mixture was stirred for 10 hours. Water and toluene were added, and the organic layer was collected by liquid separation. The organic layer was dehydrated with anhydrous sodium sulfate and thereafter concentrated under reduced pressure, to obtain 20.9 g of a colorless oil of Intermediate 6 (yield: 107%).

### Synthesis of Intermediate 7

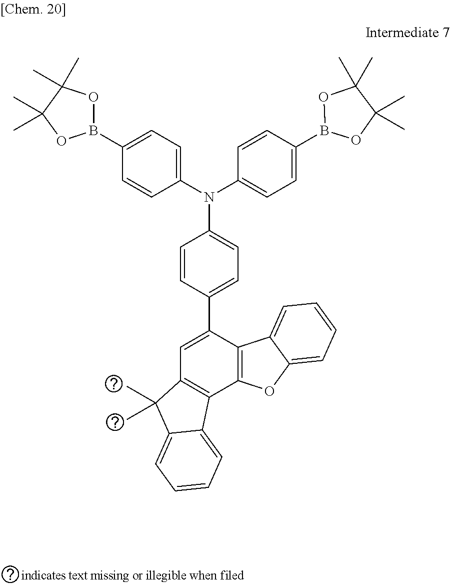

The following components were placed in a nitrogen-purged reaction vessel, and aerated with nitrogen gas for 30 minutes.
Intermediate 6: 19.4 g
Bis(pinacolato)diboron: 12.3 g
Potassium acetate: 6.5 g
1,4-Dioxane: 200 mL

Next, 0.36 g of [1,1′-bis(diphenylphosphino)ferrocene]palladium(II) dichloride dichloromethane adduct was added, and the mixture was heated and stirred at 100° C. for 6 hours. After the mixture was cooled to room temperature, water and toluene were added, and the organic layer was collected by liquid separation. The organic layer was dehydrated with anhydrous sodium sulfate and thereafter concentrated under reduced pressure, to obtain a crude product. The crude product was purified by column chromatography (toluene), to obtain 10.7 g of a white powder of Intermediate 7 (yield: 49.1%).

### Synthesis of Intermediate 8

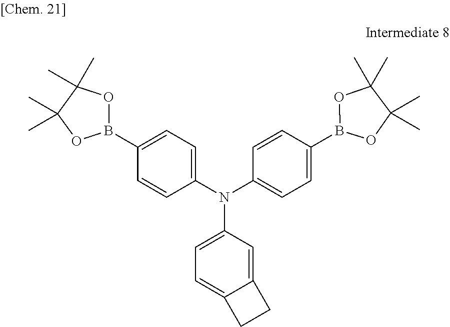

The following components were placed in a nitrogen-purged reaction vessel, and aerated with nitrogen gas for 30 minutes.
N,N-bis(4-bromophenyl)-N-(benzocyclobuten-4-yl)-amine: 8.0 g
Bis(pinacolato)diboron: 9.9 g
Potassium acetate: 4.6 g
1,4-Dioxane: 80 mL

Next, 0.3 g of [1,1-bis(diphenylphosphino)ferrocene]palladium(II) dichloride dichloromethane adduct was added, and the mixture was heated and stirred at 90° C. for 11 hours. After the mixture was cooled to room temperature, water and toluene were added, and the organic layer was collected by liquid separation. The organic layer was dehydrated with anhydrous magnesium sulfate and thereafter concentrated under reduced pressure, to obtain a crude product. The crude product was recrystallized by toluene/methanol (ratio of 1:2), to obtain 3.4 g of a white powder of Intermediate 2 (yield: 35%).

### Synthesis of Intermediate 9

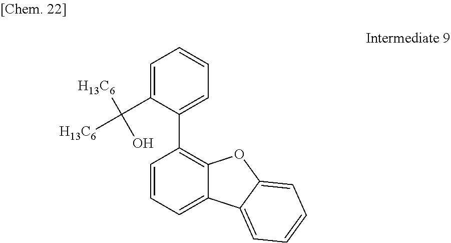

The following components were placed in a nitrogen-purged reaction vessel, and were subjected to ice cooling.
Cerium(III) chloride: 118.9 g
THF: 500 mL

Next, 482 mL of a 1 M THF solution of n-hexylmagnesium bromide was dropped slowly, and then the mixture was stirred for 1 hour. Then, Intermediate 1 dissolved in 200 mL of THF was dropped slowly, and the temperature was raised to room temperature. The mixture was stirred at room temperature for 2 hours, and then a 10 wt % aqueous solution of ammonium chloride and toluene were added, and the organic layer was collected by liquid separation. The organic layer was dehydrated with anhydrous sodium sulfate and thereafter concentrated under reduced pressure, to obtain a crude product. The crude product was washed with methanol, to obtain 54.5 g of a white solid of Intermediate 9 (yield: 76.6%).

### Synthesis of Intermediate 10

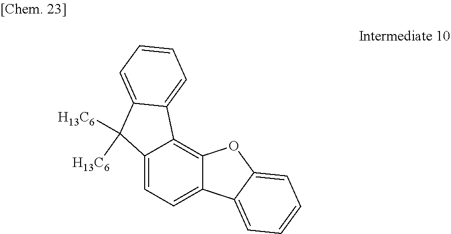

The following components were placed in a nitrogen-purged reaction vessel, and were cooled to −65° C.
Intermediate 9: 63.6 g
Dichloromethane: 640 mL

Next, 22.6 g of boron trifluoride diethyl ether complex was added and the temperature was slowly raised to room temperature, and the mixture was stirred for a total of 13 hours. A saturated aqueous solution of sodium hydrogen carbonate was added slowly, and the organic layer was collected by liquid separation. The organic layer was dehydrated with anhydrous sodium sulfate and thereafter concentrated under reduced pressure, to obtain a crude product. The crude product was washed with acetonitrile, to obtain 56.6 g of a white solid of Intermediate 10 (yield: 92.8%).

### Synthesis of Intermediate 11

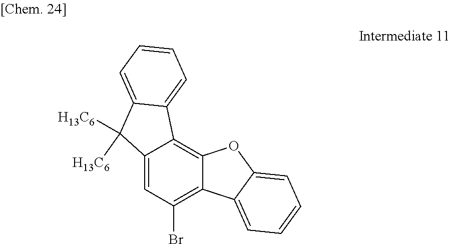

The following components were placed in a nitrogen-purged reaction vessel, and were cooled to 0° C.
Intermediate 10: 56.6 g
Dichloromethane: 560 mL

Next, 7.2 mL of bromine was added, and the mixture was stirred for 3 hours. A 10 wt % aqueous solution of sodium thiosulfate was added, and the organic layer was collected by liquid separation. The organic layer was dehydrated with anhydrous sodium sulfate and thereafter concentrated under reduced pressure, to obtain 72.4 g of a pale-yellow oil of Intermediate 11 (yield: 108.3%).

### Synthesis of Intermediate 12

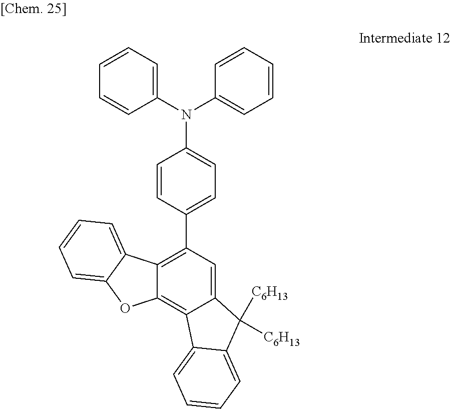

The following components were placed in a nitrogen-purged reaction vessel, and aerated with nitrogen gas for 30 minutes.
Intermediate 1: 26.0 g
Triphenylamine-4-boronic acid pinacol ester: 22.1 g
2 M aqueous solution of potassium carbonate: 40 mL
Toluene: 115 mL
Ethanol: 28 mL

Next, 0.60 g of tetrakis(triphenylphosphine)palladium(0) was added and heated, and the mixture was stirred under reflux for 23 hours. After the mixture was cooled to room temperature, water and toluene were added, and the organic layer was collected by liquid separation. The organic layer was dehydrated with anhydrous sodium sulfate and thereafter concentrated under reduced pressure, to obtain a crude product. The crude product was purified by column chromatography (n-hexane), to obtain 25.2 g of a colorless oil of Intermediate 12 (yield: 73.0%).

### Synthesis of Intermediate 13

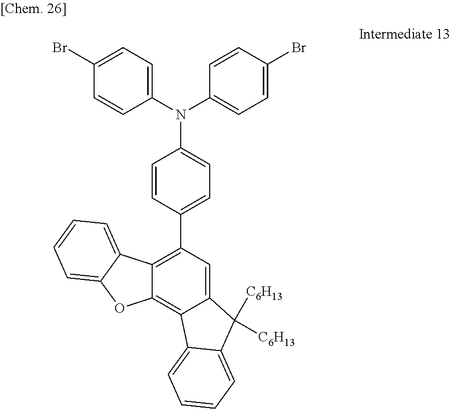

The following components were placed in a nitrogen-purged reaction vessel.
Intermediate 12: 32.1 g
THF: 325 mL

Next, 17.5 g of N-bromosuccinimide was added, and the mixture was stirred at room temperature for 12 hours. Water and toluene were added, and the organic layer was collected by liquid separation. The organic layer was dehydrated with anhydrous sodium sulfate and thereafter concentrated under reduced pressure, to obtain 41.7 g of a pale-yellow oil of Intermediate 13 (yield: 105%).

### Synthesis of Intermediate 14

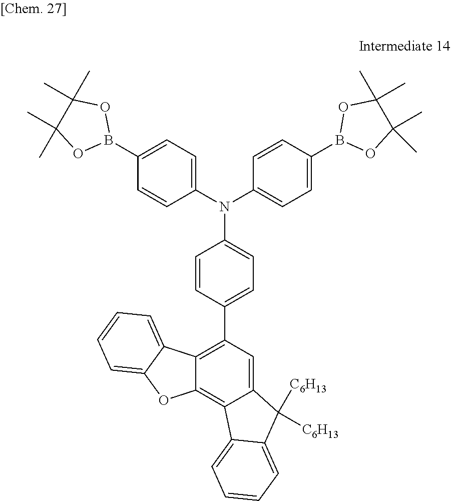

The following components were placed in a nitrogen-purged reaction vessel, and aerated with nitrogen gas for 30 minutes.
Intermediate 13: 41.0 g
Bis(pinacolato)diboron: 26.9 g
Potassium acetate: 14.2 g
1,4-Dioxane: 400 mL

Next, 0.78 g of [1,1′-bis(diphenylphosphino)ferrocene]palladium(II) dichloride dichloromethane adduct was added, and the mixture was heated and stirred at 100° C. for 10 hours. After the mixture was cooled to room temperature, water and toluene were added, and the organic layer was collected by liquid separation. The organic layer was dehydrated with anhydrous sodium sulfate and thereafter concentrated under reduced pressure, to obtain a crude product. The crude product was purified by column chromatography (toluene), to obtain 13.8 g of a white solid of Intermediate 14 (yield: 31.2%).

### Example 1

### Synthesis of High Molecular Weight Compound A:

The following components were placed in a nitrogen-purged reaction vessel, and aerated with nitrogen gas for 30 minutes.
Intermediate 7: 5.0 g
1,3-Dibromobenzene: 1.5 g
Intermediate 8: 0.7 g
Tripotassium phosphate: 5.7 g
Toluene: 9 mL
Water: 5 mL
1,4-Dioxane: 27 mL

Next, 1.2 mg of palladium(II) acetate and 9.5 mg of tri-o-tolylphosphine were added, and the mixture was heated and stirred at 82° C. for 11 hours. Then, 15 mg of phenylboronic acid was added, and the mixture was stirred for 1.5 hours. Next, 200 mg of bromobenzene was added, and the mixture was stirred for 1.5 hours. Then, 50 mL of toluene and 50 mL of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 mL of toluene; this was dropped into 300 mL of n-hexane, and the obtained precipitate was filtered and collected. This operation was repeated three times, followed by drying, to obtain 3.5 g of High molecular weight compound A (yield: 77%).

The average molecular weight measured by GPC and the degree of dispersion of High molecular weight compound A were as follows.
Number-average molecular weight Mn (in terms of polystyrene): 30,000
Weight-average molecular weight Mw (in terms of polystyrene): 52,000
Degree of dispersion (Mw/Mn): 1.7

High molecular weight compound A was also subjected to NMR measurement. FIG. 3 shows the ¹H-NMR measurement results. The chemical composition formula was as follows.

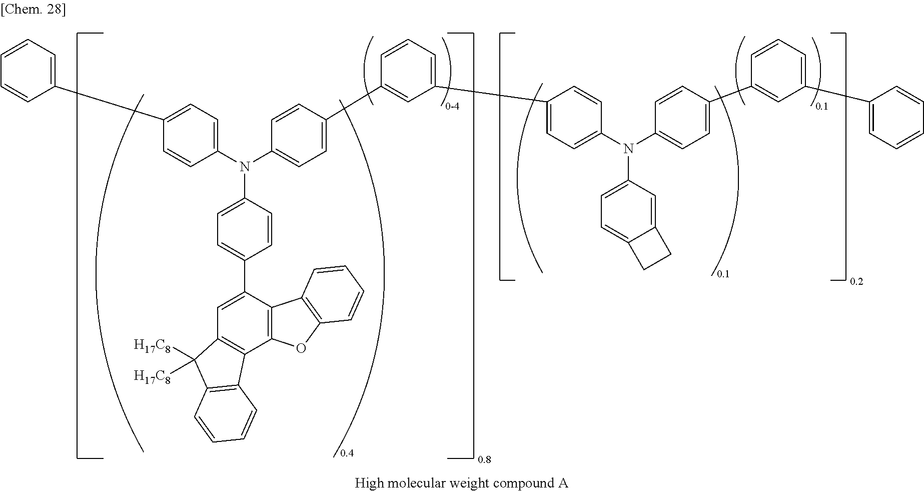

As can be understood from the chemical composition above, High molecular weight compound A contained 40 mol % of structural unit A represented by general formula (1), 50 mol % of structural unit B represented by general formula (4), and 10 mol % of thermally cross-linkable structural unit C.

### Example 2

### Synthesis of High Molecular Weight Compound B:

The following components were placed in a nitrogen-purged reaction vessel, and aerated with nitrogen gas for 30 minutes.
Intermediate 14: 6.4 g
1,3-Dibromobenzene: 1.8 g
Intermediate 8: 0.4 g
Tripotassium phosphate: 6.9 g
Toluene: 9 mL
Water: 5 mL
1,4-Dioxane: 27 mL

Next, 1.5 mg of palladium(II) acetate and 11.4 mg of tri-o-tolylphosphine were added, and the mixture was heated and stirred at 82° C. for 19 hours. Then, 18 mg of phenylboronic acid was added, and the mixture was stirred for 2 hours. Next, 243 mg of bromobenzene was added, and the mixture was stirred for 2 hours. Then, 50 mL of toluene and 50 mL of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 mL of toluene; this was dropped into 300 mL of n-hexane, and the obtained precipitate was filtered and collected. This operation was repeated three times, followed by drying, to obtain 5.0 g of High molecular weight compound B (yield: 91%).

The average molecular weight measured by GPC and the degree of dispersion of High molecular weight compound B were as follows.
Number-average molecular weight Mn (in terms of polystyrene): 22,000
Weight-average molecular weight Mw (in terms of polystyrene): 37,000
Degree of dispersion (Mw/Mn): 1.7

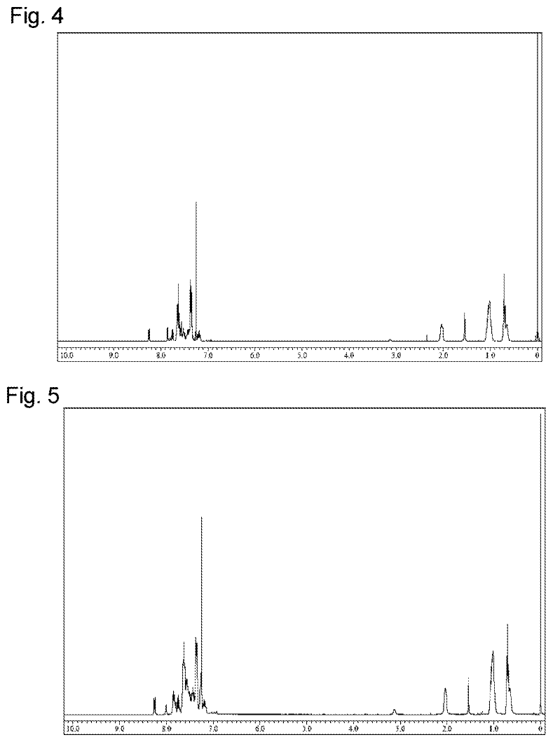

High molecular weight compound B was also subjected to NMR measurement. FIG. 4 shows the ¹H-NMR measurement results. The chemical composition formula was as follows.

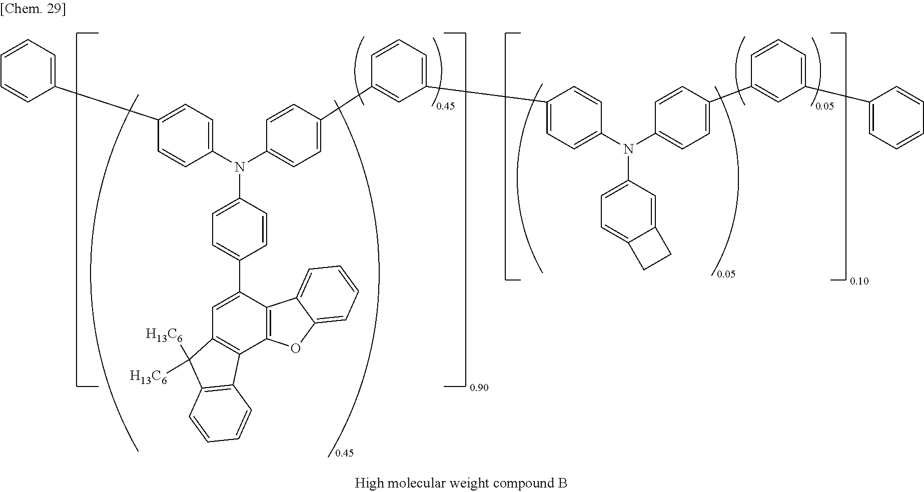

As can be understood from the chemical composition above, High molecular weight compound B contained 45 mol % of structural unit A represented by general formula (1), 50 mol % of structural unit B represented by general formula (4), and 5 mol % of thermally cross-linkable structural unit C.

### Example 31

### Synthesis of High Molecular Weight Compound C:

The following components were placed in a nitrogen-purged reaction vessel, and aerated with nitrogen gas for 30 minutes.
Intermediate 14: 4.1 g
[p-(2-Naphthyl)phenyl]bis[p-(4,4,5,5-tetramethyl-1,3,2-dioxaborolane-2-yl)phenyl]amine: 1.4 g
1,3-Dibromobenzene: 1.7 g
Intermediate 8: 0.4 g
Tripotassium phosphate: 6.5 g
Toluene: 9 mL
Water: 5 mL
1,4-Dioxane: 27 mL

Next, 1.4 mg of palladium(II) acetate and 10.6 mg of tri-o-tolylphosphine were added, and the mixture was heated and stirred at 82° C. for 21 hours. Then, 17 mg of phenylboronic acid was added, and the mixture was stirred for 2 hours. Next, 243 mg of bromobenzene was added, and the mixture was stirred for 2 hours. Then, 50 mL of toluene and 50 mL of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 mL of toluene: this was dropped into 300 mL of n-hexane, and the obtained precipitate was filtered and collected. This operation was repeated three times, followed by drying, to obtain 3.8 g of High molecular weight compound C (yield: 84%).

The average molecular weight measured by GPC and the degree of dispersion of High molecular weight compound C were as follows.
Number-average molecular weight Mn (in terms of polystyrene): 17,000
Weight-average molecular weight Mw (in terms of polystyrene): 35.000
Degree of dispersion (Mw/Mn): 2.1

High molecular weight compound C was also subjected to NMR measurement. FIG. 5 shows the ¹H-NMR measurement results. The chemical composition formula was as follows.

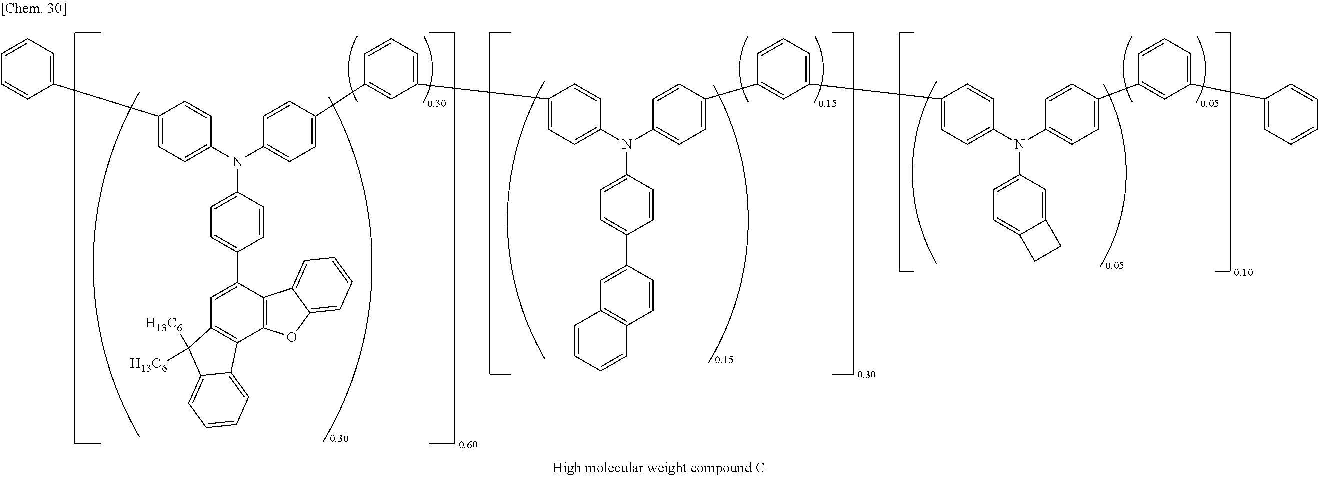

As can be understood from the chemical composition above, High molecular weight compound C contained 30 mol % of structural unit A represented by general formula (1), 50 mol % of structural unit B represented by general formula (4), 5 mol % of thermally cross-linkable structural unit C, and 15 mol % of structural unit D constituted by a triarylamine not represented by general formula (1).

### Example 41

### Work Function Measurement:

A 100-nm-thick coating film was formed on an ITO substrate by using the respective high molecular weight compounds A to C synthesized in Examples 1 to 3, and the work function was measured using an ionization potential measurement device (PYS-202 from Sumitomo Heavy Industries, Ltd.). The results are shown in Table 1.

TABLE 1

| | Work function (eV) |
|---|---|
| High molecular weight compound A | 5.77 |
| High molecular weight compound B | 5.77 |
| High molecular weight compound C | 5.75 |

The results show that the high molecular weight compounds A to C of the present invention have a suitable energy level and have good hole transportability, compared to the work function of 5.4 eV of typical hole-transporting materials such as NPD, TPD, etc.

### Example 5

### Production and Evaluation of Organic EL Device:

An organic EL device having the layer structure illustrated in FIG. 1 was produced, and its properties were evaluated.

More specifically, a glass substrate 1 having a 50-nm-thick ITO film formed thereon was washed with an organic solvent, and then, the ITO surface was cleaned by UV/ozone treatment. Then, PEDOT/PSS (from Heraeus) was spin-coated so as to cover the transparent anode 2 (ITO) provided on the glass substrate 1, thereby forming a 50-nm-thick film, and this film was dried on a hot plate at 200° C. for 10 minutes, to thereby form a hole injection layer 3.

The high molecular weight compound A obtained in Example 1 was dissolved in toluene to a concentration of 0.6 wt %, to prepare a coating liquid. The substrate provided with the hole injection layer 3 as described above was transferred to a dry nitrogen-purged glove box, and dried on a hot plate at 230° C. for 10 minutes. Then, the coating liquid was spin-coated onto the hole injection layer 3, thereby forming a 25-nm-thick coating layer, followed by drying on a hot plate at 220° C. for 30 minutes, to thereby form a hole transport layer 4.

The substrate provided with the hole transport layer 4 as described above was mounted to a vacuum deposition apparatus, in which the pressure was reduced to 0.001 Pa or lower. Then, a 34-nm-thick light-emitting layer 5 was formed on the hole transport layer 4 by binary vapor deposition by using a blue light-emitting material (EMD-1) and a host material (EMH-1) having the following structural formulas. Note that, in binary vapor deposition, the vapor deposition rate ratio between EMD-1 and EMH-1 was 4:96.

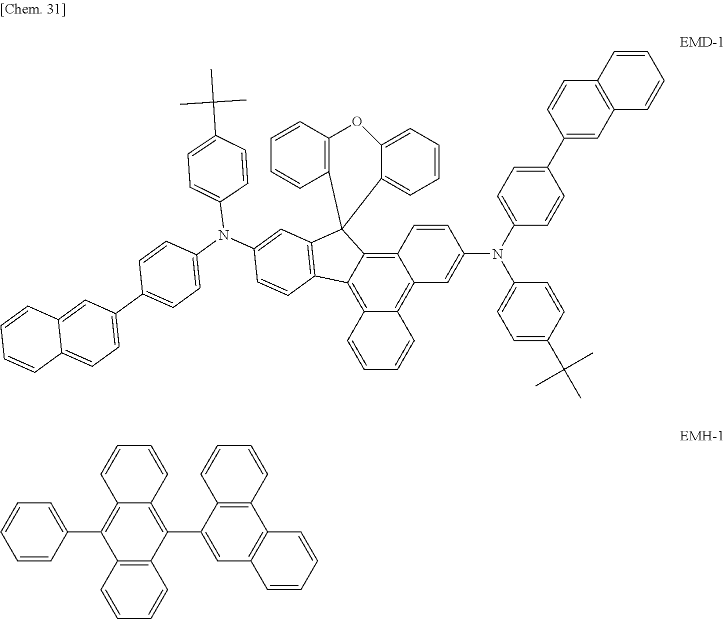

For electron-transporting materials, compounds ETM-1 and ETM-2 having the following structural formulas were prepared.

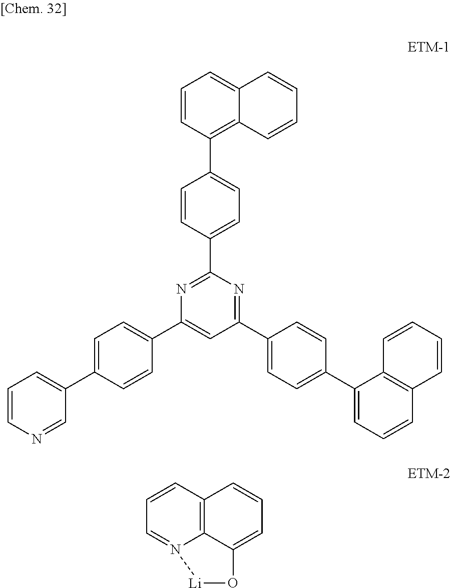

A 20-nm-thick electron transport layer 6 was formed on the aforementioned light-emitting layer 5 by binary vapor deposition by using these electron-transporting materials ETM-1 and ETM-2.

Note that, in binary vapor deposition, the vapor deposition rate ratio between ETM-1 and ETM-2 was 50:50.

Finally, aluminum was evaporatively deposited to a thickness of 100 nm, to thereby form a cathode 7.

The glass substrate, provided with the transparent anode 2, the hole injection layer 3, the hole transport layer 4, the light-emitting layer 5, the electron transport layer 6, and the cathode 7 as described above, was transferred to a dry nitrogen-purged glove box, and was then bonded with a UV curable resin to another glass substrate for sealing, thereby obtaining an organic EL device.

The properties of the produced organic EL device were measured in the atmosphere at atmospheric temperature.

Further, the light emission properties of the produced organic EL device when a direct-current voltage was applied thereto were measured.

The measurement results are shown in Table 2.

### Example 6

An organic EL device was produced in the same manner as in Example 5, except that a coating liquid prepared by dissolving, in toluene, the high molecular weight compound B obtained in Example 2 to a concentration of 0.6 wt %, instead of the high molecular weight compound A, was used to form the hole transport layer 4. For the produced organic EL device, the various properties were evaluated as in Example 5. The results are shown in Table 2.

### Example 7

An organic EL device was produced in the same manner as in Example 5, except that a coating liquid prepared by dissolving, in toluene, the high molecular weight compound C obtained in Example 3 to a concentration of 0.6 wt %, instead of the high molecular weight compound A, was used to form the hole transport layer 4. For the produced organic EL device, the various properties were evaluated as in Example 5. The results are shown in Table 2.

### Comparative Example 1

An organic EL device was produced in the same manner as in Example 5, except that a coating liquid prepared by dissolving, in toluene, the following TFB (hole transport polymer) to a concentration of 0.6 wt %, instead of the high molecular weight compound A, was used to form the hole transport layer 4.

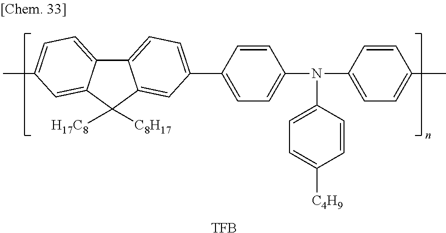

TFB (hole transport polymer) is poly[(9,9-dioctylfluorenyl-2,7-diyl)-co-(4,4′-(N-(4-sec-butylphenyl))diphenylamine] (from American Dye Source; Hole Transport Polymer ADS259BE). For the organic EL device of Comparative Example 1, the various properties were evaluated as in Example 5. The results are shown in Table 2.

In the evaluations of the various properties, the voltage, luminance, luminous efficiency, and power efficiency are values when passing a current with a current density of 10 mA/cm². The device life was found by performing constant current driving, with the light emission luminance at the start of light emission (i.e., initial luminance) set to 700 cd/m², and measuring the time it took for the light emission luminance to attenuate to 560 cd/m² (amounting to 80% w % ben the initial luminance is considered as 100%; i.e., 80% attenuation).

TABLE 2

| | High | | | Luminous | Power | |
|---|---|---|---|---|---|---|
| | molecular weight | Voltage | Luminance | efficiency | efficiency | Device life |
| | compound | [V] | [cd/m²] | [cd/A] | [lm/W] | (80% attenuation) |
| Example 5 | A | 4.56 | 973 | 9.74 | 6.71 | 13 hours |
| Example 6 | B | 4.33 | 956 | 9.57 | 6.94 | 35 hours |
| Example 7 | C | 4.29 | 936 | 9.37 | 6.87 | 38 hours |
| Comparative | TFB | 4.08 | 552 | 5.52 | 4.26 | 6 hours |
| Example 1 | | | | | | |

As shown in Table 2, while the luminous efficiency, when a current having a current density of 10 mA/cm² was passed, was 5.52 cd/A for the organic EL device of Comparative Example 1, the luminous efficiency was 9.74 cd/A for the organic EL device of Example 5, 9.57 cd/A for the organic EL device of Example 6, and 9.37 cd/A for the organic EL device of Example 7, all resulting in high efficiency. Further, while the device life (80% attenuation) was 6 hours for the organic EL device of Comparative Example 1, the device life was 13 hours for the organic EL device of Example 5, 35 hours for the organic EL device of Example 6, and 38 hours for the organic EL device of Example 7, all resulting in long lifetime.

### Example 8

An organic EL device having the layer structure illustrated in FIG. 2 was produced, and its properties were evaluated.

More specifically, a glass substrate 8 having a 50-nm-thick ITO film formed thereon was washed with an organic solvent, and then, the ITO surface was cleaned by UV/ozone treatment. Then, PEDOT/PSS (from Heraeus) was spin-coated so as to cover the transparent anode 9 (ITO) provided on the glass substrate 8, thereby forming a 50-nm-thick film, and this film was dried on a hot plate at 200° C. for 10 minutes, to thereby form a hole injection layer 10.

A high molecular weight compound HTM-1 having the following structural formula was dissolved in toluene to a concentration of 0.4 wt %, to prepare a coating liquid. The substrate provided with the hole injection layer 10 as described above was transferred to a dry nitrogen-purged glove box, and dried on a hot plate at 230° C. for 10 minutes. Then, the coating liquid was spin-coated onto the hole injection layer 10, thereby forming a 15-nm-thick coating layer, followed by drying on a hot plate at 220° C. for 30 minutes, to thereby form a hole transport layer 11.

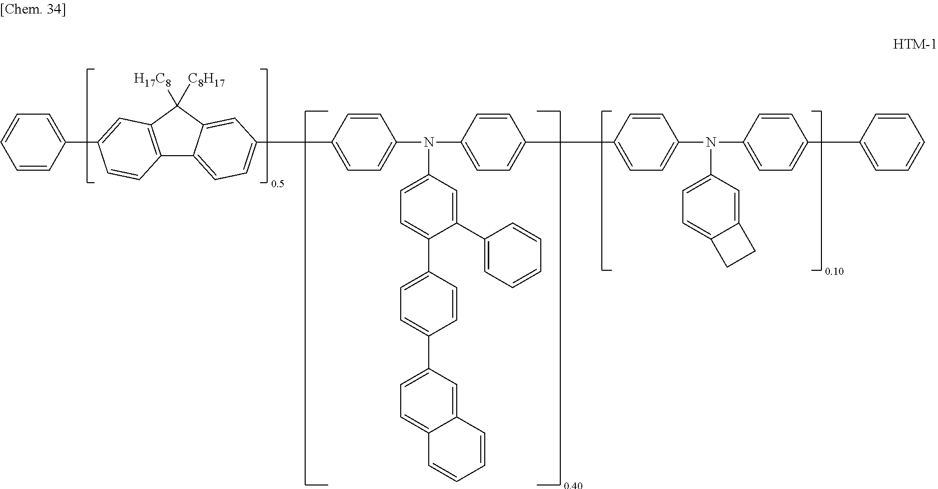

The high molecular weight compound A obtained in Example 1 was dissolved in toluene to a concentration of 0.4 wt %, to prepare a coating liquid. The coating liquid was spin-coated onto the hole transport layer 11, thereby forming a 15-nm-thick coating layer, followed by drying on a hot plate at 220° C. for 30 minutes, to thereby form an electron blocking layer 12.

The substrate provided with the electron blocking layer 12 as described above was mounted to a vacuum deposition apparatus, in which the pressure was reduced to 0.001 Pa or lower. Then, a 34-nm-thick light-emitting layer 13 was formed on the electron blocking layer 12 by binary vapor deposition by using the blue light-emitting material (EMD-1) and the host material (EMH-1). Note that, in binary vapor deposition, the vapor deposition rate ratio between EMD-1 and EMH-1 was 4:96.

A 20-nm-thick electron transport layer 14 was formed on the aforementioned light-emitting layer 13 by binary vapor deposition by using the electron-transporting materials ETM-1 and ETM-2. Note that, in binary vapor deposition, the vapor deposition rate ratio between ETM-1 and ETM-2 was 50:50.

Finally, aluminum was evaporatively deposited to a thickness of 100 nm, to thereby form a cathode 15.

The glass substrate, provided with the transparent anode 9, the hole injection layer 10, the hole transport layer 11, the electron blocking layer 12, the light-emitting layer 13, the electron transport layer 14, and the cathode 15 as described above, was transferred to a dry nitrogen-purged glove box, and was then bonded with a UV curable resin to another glass substrate for sealing, thereby obtaining an organic EL device. The properties of the produced organic EL device were measured in the atmosphere at atmospheric temperature. Further, the light emission properties of the produced organic EL device when a direct-current voltage was applied thereto were measured. The measurement results are shown in Table 3.

### Example 9

An organic EL device was produced in the same manner as in Example 8, except that a coating liquid prepared by dissolving, in toluene, the high molecular weight compound B obtained in Example 2 to a concentration of 0.4 wt %, instead of the high molecular weight compound A, was used to form the electron blocking layer 12. The properties of the produced organic EL device were measured in the atmosphere at atmospheric temperature. The measurement results of light emission properties of the produced organic EL device when a direct-current voltage was applied thereto are collectively shown in Table 3.

### Example 10

An organic EL device was produced in the same manner as in Example 8, except that a coating liquid prepared by dissolving, in toluene, the high molecular weight compound C obtained in Example 3 to a concentration of 0.4 wt %, instead of the high molecular weight compound A, was used to form the electron blocking layer 12. The properties of the produced organic EL device were measured in the atmosphere at atmospheric temperature. The measurement results of light emission properties of the produced organic EL device when a direct-current voltage was applied thereto are collectively shown in Table 3.

### Comparative Example 2

An organic EL device having the layer structure illustrated in FIG. 1 was produced, and its properties were evaluated.

More specifically, a glass substrate 1 having a 50-nm-thick ITO film formed thereon was washed with an organic solvent, and then, the ITO surface was cleaned by UV/ozone treatment. Then, PEDOT/PSS (from Heraeus) was spin-coated so as to cover the transparent anode 2 (ITO) provided on the glass substrate 1, thereby forming a 50-nm-thick film, and this film was dried on a hot plate at 200° C. for 10 minutes, to thereby form a hole injection layer 3.

The high molecular weight compound HTM-1 was dissolved in toluene to a concentration of 0.6 wt %, to prepare a coating liquid. The substrate provided with the hole injection layer 3 as described above was transferred to a dry nitrogen-purged glove box, and the coating liquid was spin-coated onto the hole injection layer 3, thereby forming a 25-nm-thick coating layer, followed by drying on a hot plate at 220° C. for 30 minutes, to thereby form a hole transport layer 4.

The substrate provided with the hole transport layer 4 as described above was mounted to a vacuum deposition apparatus, in which the pressure was reduced to 0.001 Pa or lower. Then, a 34-nm-thick light-emitting layer 5 was formed on the hole transport layer 4 by binary vapor deposition by using the blue light-emitting material (EMD-1) and the host material (EMH-1). Note that, in binary vapor deposition, the vapor deposition rate ratio between EMD-1 and EMH-1 was 4:96.

A 20-nm-thick electron transport layer 6 was formed on the aforementioned light-emitting layer 5 by binary vapor deposition by using the electron-transporting materials ETM-1 and ETM-2. Note that, in binary vapor deposition, the vapor deposition rate ratio between ETM-1 and ETM-2 was 50:50.

Finally, aluminum was evaporatively deposited to a thickness of 100 nm, to thereby form a cathode 7.

The glass substrate, provided with the transparent anode 2, the hole injection layer 3, the hole transport layer 4, the light-emitting layer 5, the electron transport layer 6, and the cathode 7 as described above, was transferred to a dry nitrogen-purged glove box, and was then bonded with a UV curable resin to another glass substrate for sealing, thereby obtaining an organic EL device. The properties of the produced organic EL device were measured in the atmosphere at atmospheric temperature. Further, the light emission properties of the produced organic EL device when a direct-current voltage was applied thereto were measured. The measurement results are shown in Table 3.

In the evaluations of the various properties, the voltage, luminance, luminous efficiency, and power efficiency are values when passing a current with a current density of 10 mA/cm². The device life was found by performing constant current driving, with the light emission luminance at the start of light emission (i.e., initial luminance) set to 700 cd/m², and measuring the time it took for the light emission luminance to attenuate to 560 cd/m² (amounting to 80% when the initial luminance is considered as 100%: i.e., 80% attenuation).

TABLE 3

| | | | | Luminous | Power | |
|---|---|---|---|---|---|---|
| | Electron blocking | Voltage | Luminance | efficiency | efficiency | Device life |
| | layer | [V] | [cd/m²] | [cd/A] | [lm/W] | (80% attenuation) |
| Example 8 | High molecular | 4.24 | 930 | 9.30 | 6.89 | 41 hours |
| | weight compound | | | | | |
| | A | | | | | |
| Example 9 | High molecular | 3.97 | 888 | 8.88 | 7.03 | 73 hours |
| | weight compound | | | | | |
| | B | | | | | |
| Example 10 | High molecular | 4.01 | 855 | 8.55 | 6.70 | 63 hours |
| | weight compound | | | | | |
| | C | | | | | |
| Comparative | None | 3.89 | 757 | 7.56 | 6.12 | 20 hours |
| Example 2 | | | | | | |

As shown in Table 3, while the luminous efficiency, when a current having a current density of 10 mA/cm² was passed, was 7.56 cd/A for the organic EL device of Comparative Example 2, the luminous efficiency was 9.30 cd/A for the organic EL device of Example 8, 8.88 cd/A for the organic EL device of Example 9, and 8.55 cd/A for the organic EL device of Example 10, all resulting in high efficiency. Further, while the device life (80% attenuation) was 20 hours for the organic EL device of Comparative Example 2, the device life was 41 hours for the organic EL device of Example 8, 73 hours for the organic EL device of Example 9, and 63 hours for the organic EL device of Example 10, all resulting in long lifetime.

The above results show that organic EL devices provided with an organic layer formed using high molecular weight compounds of the present invention can achieve higher luminous efficiency and longer lifetime compared to conventional organic EL devices.

### INDUSTRIAL APPLICABILITY

The high molecular weight compound of the present invention has high hole transportability, excellent electron blockability, and excellent thermal cross-linkability, and is thus an excellent compound for coating-type organic EL devices. By producing a coating-type organic EL device using this compound, it is possible to achieve high luminous efficiency and power efficiency, and also improve durability. Thus, for example, application can be expanded to a wide variety of uses, such as home electrical appliances and lightings.

### REFERENCE SIGNS LIST

1, 8: Glass substrate
2, 9: Transparent anode
3, 10: Hole injection layer
4, 11: Hole transport laver
5, 13: Light-emitting layer
6, 14: Electron transport layer
7, 15: Cathode
12: Electron blocking layer

1. A high molecular weight compound comprising, as a repeating unit, a triarylamine structural unit having an indeno-dibenzoheterole structure represented by general formula (1) below as a partial structure: 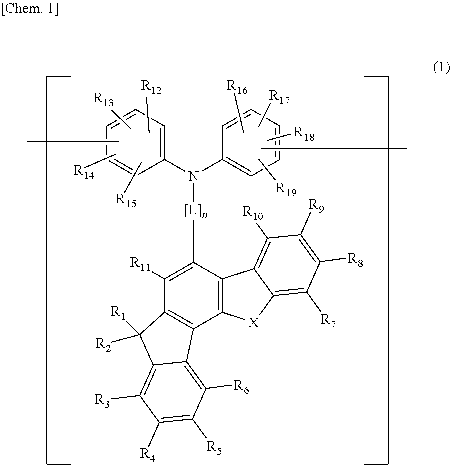
(wherein:
R₁ and R₂ each independently represent a substituted or unsubstituted alkyl group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, or a substituted or unsubstituted polyether group having 1 to 40 carbon atoms;
X represents an oxygen atom or a sulfur atom;
R₃ to Ru each independently represent a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, a substituted or unsubstituted aryloxy group, a substituted or unsubstituted aryl group, or a substituted or unsubstituted heteroaryl group;
R₁₂ and R₁₆ each independently represent a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, or a substituted or unsubstituted aryloxy group, wherein R₁₂ and R₁₆ may be bonded to each other via a single bond, a methylene group optionally having a substituent, an oxygen atom, or a sulfur atom;
R₁₃ to R₁₅ and R₁₇ to Rig each independently represent a hydrogen atom or a deuterium atom;
L represents a substituted or unsubstituted arylene group having 5 to 40 carbon atoms; and
n represents an integer from 0 to 3).

2. The high molecular weight compound according to claim 1, comprising a repeating unit represented by general formula (2) below: 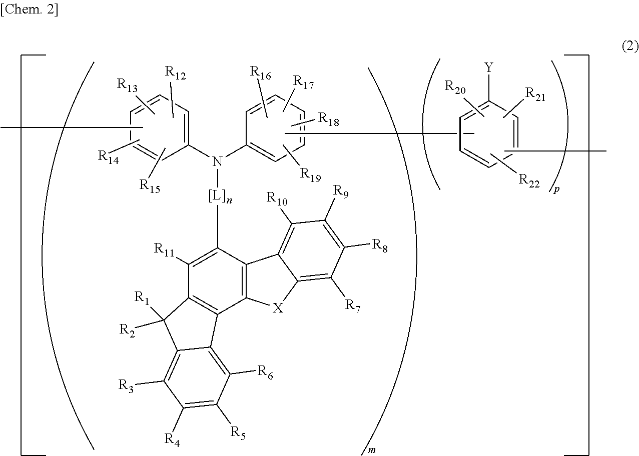
(wherein:
R₁ to Rig, X, L, and n are the same as in general formula (1);
R₂₀ to R₂₂ each independently represent a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, or a substituted or unsubstituted aryloxy group;
Y represents a hydrogen atom, a deuterium atom, a substituted or unsubstituted amino group, a substituted or unsubstituted aryl group, or a substituted or unsubstituted heteroaryl group;
m and p are expressed in mole fraction;
m represents from 0.1 to 0.9; and
p represents from 0.1 to 0.9).

3. The high molecular weight compound according to claim 1, wherein X is an oxygen atom.

4. The high molecular weight compound according to claim 1, wherein R₁₂ to R₁₉ are each a hydrogen atom.

5. The high molecular weight compound according to claim 1, wherein R₃ to R₁₁ are each a hydrogen atom.

6. The high molecular weight compound according to claim 2, wherein R₃ to R₂₂ are each a hydrogen atom.

7. The high molecular weight compound according to claim 2, wherein Y is a hydrogen atom, a diphenylamino group, a phenyl group, a naphthyl group, a dibenzofuranyl group, a dibenzothienyl group, a phenanthrenyl group, a fluorenyl group, a carbazolyl group, an indenocarbazolyl group, or an acridinyl group.

8. The high molecular weight compound according to claim 1, wherein R₁ and R₂ each independently represent an alkyl group, an alkyloxy group, or a polyether group.

9. The high molecular weight compound according to claim 1, comprising a thermally cross-linkable structural unit as a repeating unit.

10. The high molecular weight compound according to claim 9, wherein the thermally cross-linkable structural unit is at least one type of thermally cross-linkable structural unit selected from the group consisting of general formulas (3aa) to (3bd) below: 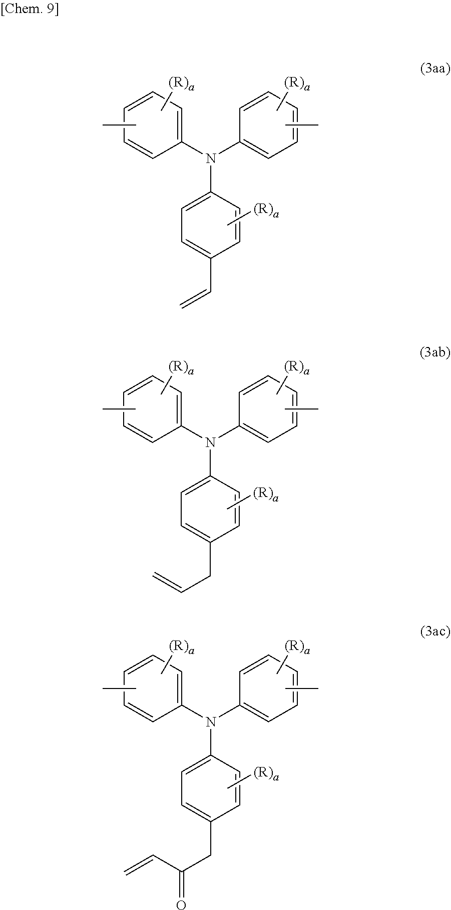 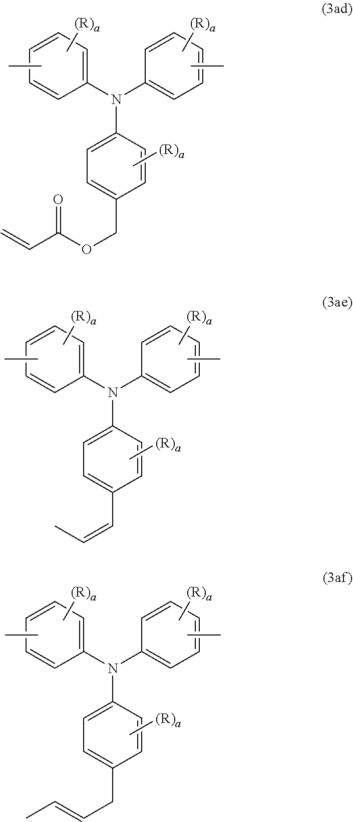 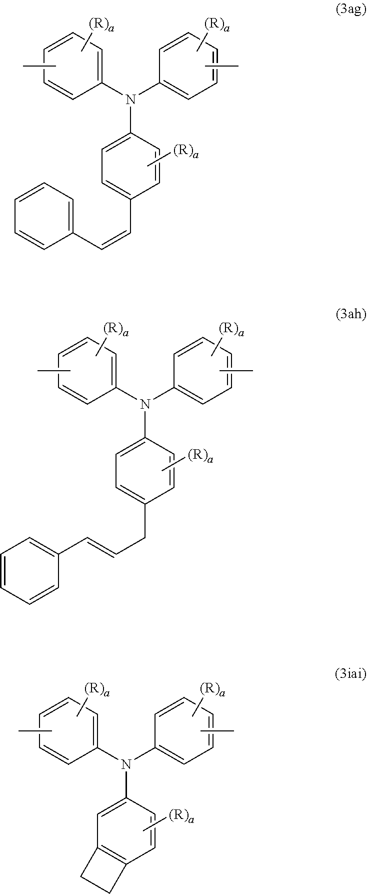 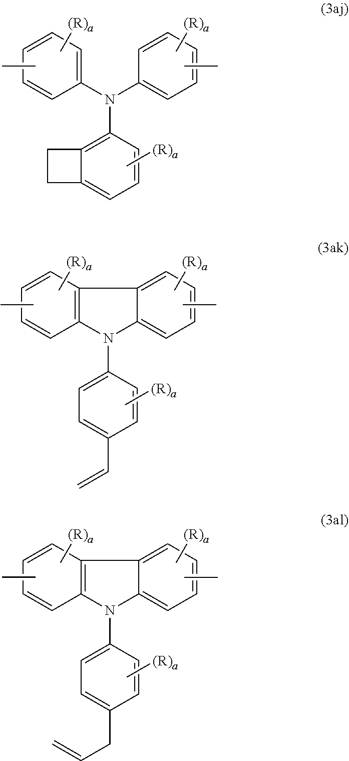 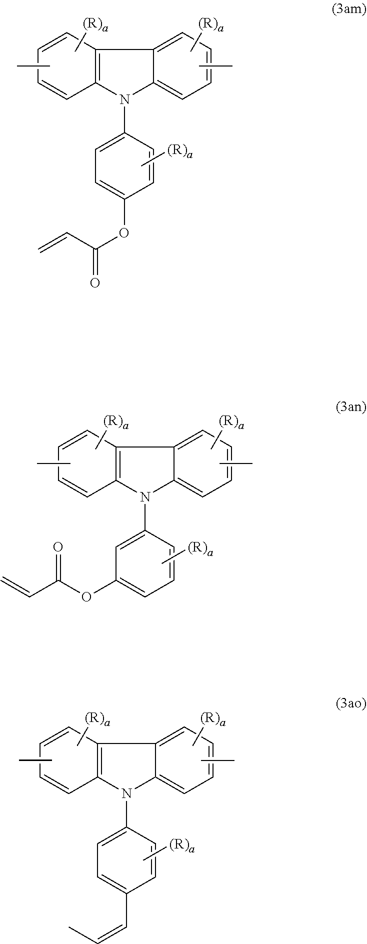 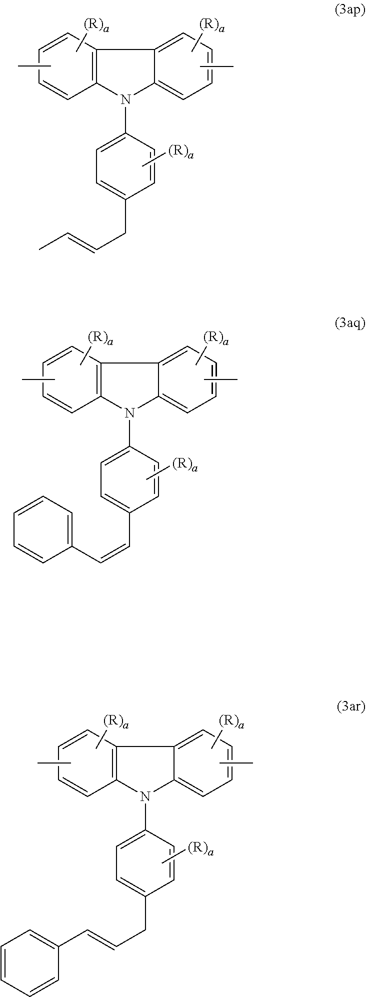 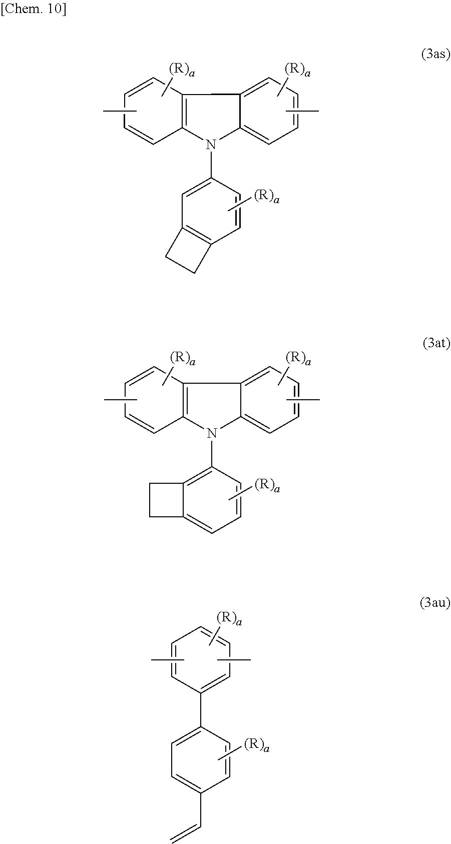 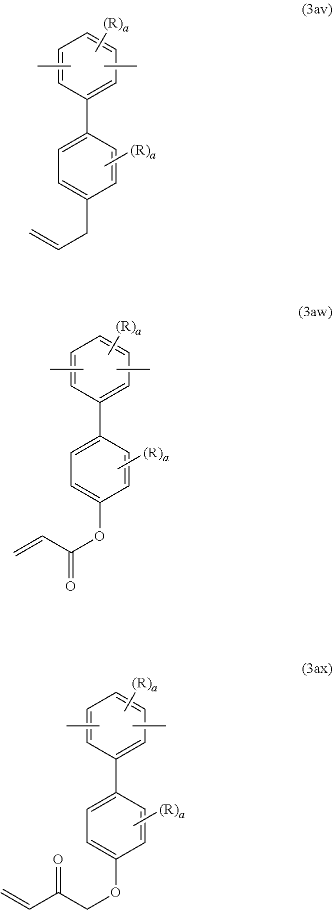 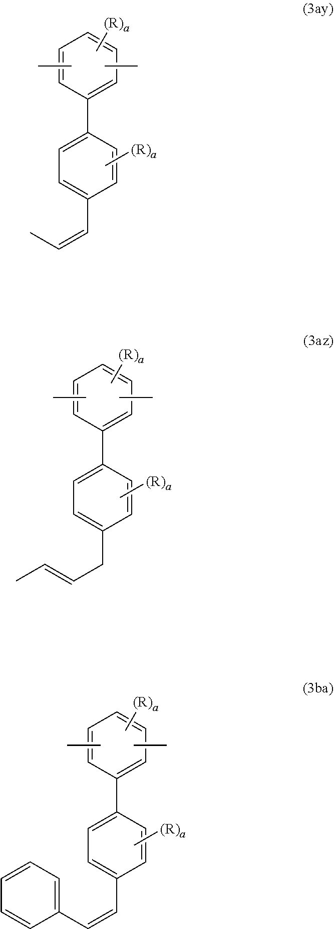 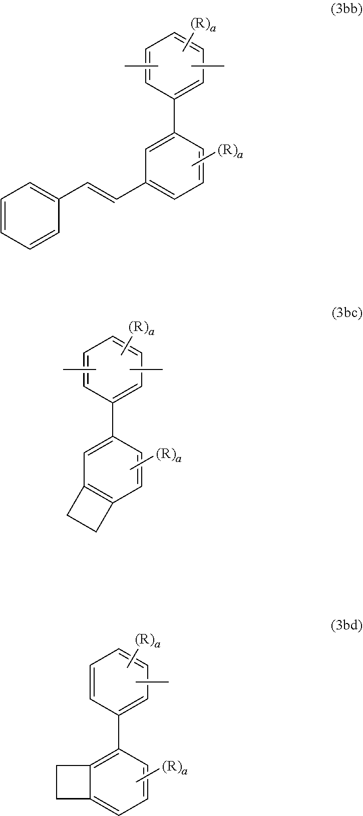
(wherein:
R independently represents a hydrogen atom, a deuterium atom, a cyano group, a nitro group, a halogen atom, a substituted or unsubstituted alkyl group having 1 to 40 carbon atoms, a substituted or unsubstituted polyether group having 1 to 40 carbon atoms, a substituted or unsubstituted cycloalkyl group having 3 to 40 carbon atoms, a substituted or unsubstituted alkyloxy group having 1 to 40 carbon atoms, a substituted or unsubstituted cycloalkyloxy group having 3 to 40 carbon atoms, a substituted or unsubstituted alkenyl group having 2 to 40 carbon atoms, a substituted or unsubstituted aryloxy group, a substituted or unsubstituted aryl group, or a substituted or unsubstituted heteroaryl group;
a wavy line represents cis or trans;
a dotted line represents a bond to a main chain;
a represents an integer from 0 to 4; and
b represents an integer from 0 to 3).

11. An organic electroluminescent device comprising a pair of electrodes, and at least one layer of an organic layer interposed therebetween, wherein the organic layer contains the high molecular weight compound according to claim 1.

12. The organic electroluminescent device according to claim 11, wherein the organic layer is a hole transport layer.

13. The organic electroluminescent device according to claim 11, wherein the organic layer is an electron blocking layer.

14. The organic electroluminescent device according to claim 11, wherein the organic layer is a hole injection layer.

15. The organic electroluminescent device according to claim 11, wherein the organic layer is a light-emitting layer.
